(19) United States
(12) Patent Application Publication
(10) Pub. No.: US 2023/0146778 A1
(43) Pub. Date: May 11, 2023

(54) System and Method for Electrical Power Line Failure Detection

(71) Applicant: Trackonomy Systems, Inc., San Jose, CA (US)

(72) Inventors: Hendrik J Volkerink, Palo Alto, CA (US); Ajay Khoche, West San Jose, CA (US); Lawrence William Mcgary, Jr., Pacific Palisades, CA (US)

(21) Appl. No.: 17/983,378

(22) Filed: Nov. 8, 2022

Related U.S. Application Data
(60) Provisional application No. 63/276,785, filed on Nov. 8, 2021.
(60) Provisional application No. 63/338,029, filed on May 4, 2022.

(51) Int. Cl. G01R 31/08; G01R 15/12; G01R 15/24; G01R 15/14

(52) U.S. Cl. CPC G01R 31/085; G01R 15/12; G01R 15/144; G01R 15/146; G01R 15/247; G01R 15/202

(57) ABSTRACT

A wireless tracking device includes circuit components, a battery, and a circuit connecting the circuit components and the battery. The circuit components include a first wireless communication system, a processor, a memory or storage, and a first sensor operable to measure conditions of the wireless tracking device. The wireless tracking device is configured to attach to an overhead electrical line and detect failure events that are experienced by the overhead electrical line based on sensor data monitored by the wireless tracking device.

### FIELD OF THE DISCLOSURE

This disclosure generally relates to sensor devices and networks of sensor devices.

### BACKGROUND

Failure of an electrical power line can create a loss of service or even an emergency situation, such as a fire or other hazard. It is desirable to detect a failure of an electrical power line before a major loss of service or emergency occurs.

### SUMMARY

A wireless tracking device is disclosed which is attached to an electrical power line and detects failure states of the electrical power line. The wireless tracking device, for example, may detect when an electrical power line falls from a utility structure (e.g., a utility pole or transmission tower) using one or more sensors of the wireless tracking device. In some embodiments, the wireless tracking device is an embodiment of an adhesive tape platform. The wireless tracking device detects failure states of the electrical power lien and wirelessly reports the failure states to a tracking system with low latency.

A wireless tracking device includes circuit components, a battery, and a circuit connecting the circuit components and the battery. The circuit components include a first wireless communication system, a processor, a memory or storage, and a first sensor operable to measure conditions of the wireless tracking device. The wireless tracking device is configured to attach to an overhead electrical line and detect failure events that are experienced by the overhead electrical line based on sensor data monitored by the wireless tracking device.

A system for failure detection in infrastructure components of an electrical grid include a first plurality of failure detecting wireless tracking devices each attached to a respective overhead electrical line of an electrical grid, a second plurality of failure detecting wireless tracking devices each attached to a respective transmission tower or electrical pole of the electrical grid, a third plurality of failure detecting wireless tracking devices each attached to a transformer of the electrical grid, and a server which executes a server application that communicates with and collects data from the first, second, and third plurality of failure detecting wireless tracking devices, wherein the server maintains a database storing data for the system.

Each of the first plurality of failure detecting wireless tracking devices is configured to detect failure events of the respective overhead electrical lines based on sensor data collected by the first plurality of failure detecting wireless tracking devices. Each of the second plurality of failure detecting wireless tracking devices is configured to detect failure events of the respective transmission tower or electrical pole based on sensor data collected by the second plurality of failure detecting wireless tracking devices. Each of the third plurality of failure detecting wireless tracking devices is configured to detect failure events of the respective transformer based on sensor data collected by the third plurality of failure detecting wireless tracking devices.

### BRIEF DESCRIPTION OF THE DRAWINGS

FIG. 1A is a diagrammatic view of an asset that has been sealed for shipment using a segment of an example adhesive tape platform dispensed from a roll, according to some embodiments.

FIG. 1B is a diagrammatic top view of a portion of the segment of the example adhesive tape platform shown in FIG. 1A, according to some embodiments.

FIG. 2 is a diagrammatic view of an example of an envelope carrying a segment of an example adhesive tape platform dispensed from a backing sheet, according to some embodiments.

FIG. 3 is a schematic view of an example segment of an adhesive tape platform, according to some embodiments.

FIG. 4 is a diagrammatic top view of a length of an example adhesive tape platform, according to some embodiments.

FIGS. 5A-5C show diagrammatic cross-sectional side views of portions of different respective adhesive tape platforms, according to some embodiments.

FIGS. 6A-6B are diagrammatic top views of a length of an example adhesive tape platform, according to some embodiments.

FIG. 6C is a diagrammatic view of a length of an example adhesive tape platform adhered to an asset, according to some embodiments.

FIG. 7 is a diagrammatic view of an example of a network environment supporting communications with segments of an adhesive tape platform, according to some embodiments.

FIG. 8 is a diagrammatic view of a hierarchical communications network, according to some embodiments.

FIG. 9 is a flow diagram of a method of creating a hierarchical communications network, according to some embodiments.

FIGS. 10A-10E are diagrammatic views of exemplary use cases for a distributed agent operating system, according to some embodiments.

FIGS. 11A-11B show example states of overhead electrical power lines according to some embodiments.

FIGS. 12A-12B show examples of detecting failure states of overhead electrical power lines 1210A, 1210B using failure detecting tape nodes according to some embodiments.

FIGS. 12C-12F show various examples of failure detecting tape components, according to some embodiments.

FIG. 12G shows an example of using an array of failure detecting tape nodes on a respective electrical power line to detect a failure state of the electrical power line, according to some embodiments.

FIG. 13 is a flow chart for an example method of detecting that an overhead line has fallen, according to some embodiments.

FIG. 14 is a flow chart for an example method of detecting a failure state of an electrical line, according to some embodiments.

FIGS. 15A-15B show examples of failure detecting tape nodes, according to various embodiments.

FIG. 16 is an example diagram of a client device displaying an installation interface for an app used to track tape nodes installed on electrical lines, according to some embodiments.

FIG. 17 is an example diagram of a client device 1701 displaying a map viewing interface for an app used to track tape nodes and other wireless nodes of the tracking system 400 installed on or near electrical lines 1720 and other electrical grid infrastructure components, according to some embodiments.

FIG. 18 is a flow chart for an example method of assigning a location to a failure detecting tape node using an installation interface on a client device app, according to some embodiments.

FIG. 19 is a flow chart for an example method of displaying the locations of and data from failure detecting tape nodes on a map viewing interface on a client device app, according to some embodiments.

FIG. 20 shows an example portion of a system for detecting failure events for infrastructure components of an electrical grid, according to some embodiments.

FIG. 21 is an interaction diagram for an example portion of a system for detecting failure events for infrastructure components of an electrical grid, according to some embodiments.

FIG. 22 is a flow chart for an example method of determining locations of potential points of failure in an electrical grid, according to some embodiments.

FIG. 23 shows an example embodiment of computer apparatus, according to some embodiments.

### DETAILED DESCRIPTION

Failure of an electrical power line can create a loss of service or even an emergency situation, such as a fire or other hazard. It is desirable to detect a failure of an electrical power line before a major loss of service or emergency occurs.

Failure detecting tape nodes are attached to electrical power line (e.g., overhead power line). Failure detecting tape nodes are configured to detect a failure state of the electrical power line. An example failure state would be a state where an overhead power line has fallen down or fallen off of an electrical pole, tower (e.g., transmission tower), utility pole, or some other structure. Failure detection for electrical or overhead lines using the failure detecting tape node is not limited to detecting failure in electrical power lines. In some embodiments, failure detection may be used to detect failure in any line or object that is suspended in the air or hung overhead.

The failure detecting tape nodes are part of a failure detection system which enables low latency, continuous detection of failure states and failure events. The failure detection system includes the tracking system 400 or components of the tracking system 400. Failure events are events that may results in a potential failure state of the line. The failure detection system may be coupled to a controlling system of the electrical grid that allows the electrical grid to disable or deenergize a transformer when a nearby or associated power line falls or experiences a failure state.

In some embodiments, the wireless IOT device is an adhesive tape platform or a segment thereof. The adhesive tape platform includes wireless transducing components and circuitry that perform communication and/or sensing. The adhesive tape platform has a flexible adhesive tape form-factor that allows it to function as both an adhesive tape for adhering to and/or sealing objects and a wireless sensing device.

In the following description, like reference numbers are used to identify like elements. Furthermore, the drawings are intended to illustrate major features of exemplary embodiments in a diagrammatic manner. The drawings are not intended to depict every feature of actual embodiments nor relative dimensions of the depicted elements and are not drawn to scale.

As used herein, the term “or” refers to an inclusive “or” rather than an exclusive “or.” In addition, the articles “a” and “an” as used in the specification and claims mean “one or more” unless specified otherwise or clear from the context to refer the singular form.

The term “tape node” refers to an adhesive tape platform or a segment thereof that is equipped with sensor, processor, memory, energy source/harvesting mechanism, and wireless communications functionality, where the adhesive tape platform (also referred to herein as an “adhesive product” or an “adhesive tape product”) has a variety of different form factors, including a multilayer roll or a sheet that includes a plurality of divisible adhesive segments. Once deployed, each tape node can function, for example, as an adhesive tape, label, sticker, decal, or the like, and as a wireless communications device.

The terms “adhesive tape node,” “wireless node,” or “tape node” may be used interchangeably in certain contexts, and refer to an adhesive tape platform or a segment thereof that is equipped with sensor, processor, memory, energy source/harvesting mechanism, and wireless communications functionality, where the adhesive product has a variety of different form factors, including a multilayer roll or a sheet that includes a plurality of divisible adhesive segments. Once deployed, each tape node or wireless node can function, for example, as an adhesive tape, label, sticker, decal, or the like, and as a wireless communications device. A “peripheral” tape node or “peripheral” wireless node, also referred to as an outer node, leaf node, or terminal node, refers to a node that does not have any child nodes.

In some instances, a “wireless node” may refer to a node or wireless device of the wireless tracking system that is not an adhesive tape platform. For example, a wireless node, in some embodiments, may have a form factor that is not flexible or may not include an adhesive.

In certain contexts, the terms “parcel,” “envelope,” “box,” “package,” “container,” “pallet,” “carton,” “wrapping,” and the like are used interchangeably herein to refer to a packaged item or items.

In certain contexts, the terms “wireless tracking system,” “hierarchical communications network,” “distributed agent operating system,” and the like are used interchangeably herein to refer to a system or network of wireless nodes.

### Introduction

This specification describes a low-cost, multi-function adhesive tape platform with a form factor that unobtrusively integrates the components useful for implementing a combination of different asset tracking and management functions and also is able to perform a useful ancillary function that otherwise would have to be performed with the attendant need for additional materials, labor, and expense. In an aspect, the adhesive tape platform is implemented as a collection of adhesive products that integrate wireless communications and sensing components within a flexible adhesive structure in a way that not only provides a cost-effective platform for interconnecting, optimizing, and protecting the components of the tracking system but also maintains the flexibility needed to function as an adhesive product that can be deployed seamlessly and unobtrusively into various asset management and tracking applications and workflows, including person and object tracking applications, and asset management workflows such as manufacturing, storage, shipping, delivery, and other logistics associated with moving products and other physical objects, including logistics, sensing, tracking, locationing, warehousing, parking, safety, construction, event detection, road management and infrastructure, security, and healthcare. In some examples, the adhesive tape platforms are used in various aspects of asset management, including sealing assets, transporting assets, tracking assets, monitoring the conditions of assets, inventorying assets, and verifying asset security. In these examples, the assets typically are transported from one location to another by truck, train, ship, or aircraft or within premises, e.g., warehouses by forklift, trolleys etc.

In disclosed examples, an adhesive tape platform includes a plurality of segments that can be separated from the adhesive product (e.g., by cutting, tearing, peeling, or the like) and adhesively attached to a variety of different surfaces to inconspicuously implement any of a wide variety of different wireless communications based network communications and transducing (e.g., sensing, actuating, etc.) applications. Examples of such applications include: event detection applications, monitoring applications, security applications, notification applications, and tracking applications, including inventory tracking, asset tracking, person tracking, animal (e.g., pet) tracking, manufactured parts tracking, and vehicle tracking. In example embodiments, each segment of an adhesive tape platform is equipped with an energy source, wireless communication functionality, transducing functionality, and processing functionality that enable the segment to perform one or more transducing functions and report the results to a remote server or other computer system directly or through a network of tapes. The components of the adhesive tape platform are encapsulated within a flexible adhesive structure that protects the components from damage while maintaining the flexibility needed to function as an adhesive tape (e.g., duct tape or a label) for use in various applications and workflows. In addition to single function applications, example embodiments also include multiple transducers (e.g., sensing and/or actuating transducers) that extend the utility of the platform by, for example, providing supplemental information and functionality relating characteristics of the state and or environment of, for example, an article, object, vehicle, or person, over time.

Systems and processes for fabricating flexible multifunction adhesive tape platforms in efficient and low-cost ways also are described. In addition to using roll-to-roll and/or sheet-to-sheet manufacturing techniques, the fabrication systems and processes are configured to optimize the placement and integration of components within the flexible adhesive structure to achieve high flexibility and ruggedness. These fabrication systems and processes are able to create useful and reliable adhesive tape platforms that can provide local sensing, wireless transmitting, and locationing functionalities. Such functionality together with the low cost of production is expected to encourage the ubiquitous deployment of adhesive tape platform segments and thereby alleviate at least some of the problems arising from gaps in conventional infrastructure coverage that prevent continuous monitoring, event detection, security, tracking, and other asset tracking and management applications across heterogeneous environments.

### Adhesive Tape Platform

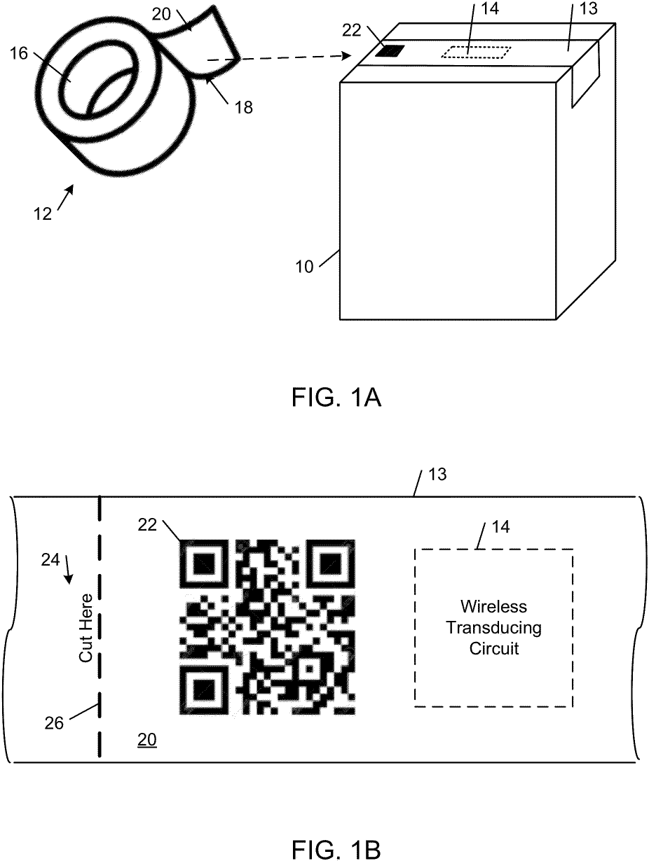

FIG. 1A shows an example asset 10 that is sealed for shipment using an example adhesive tape platform 12 that includes embedded components of a wireless transducing circuit 14 (collectively referred to herein as a “tape node”). In this example, a length 13 of the adhesive tape platform 12 is dispensed from a roll 16 and affixed to the asset 10. The adhesive tape platform 12 includes an adhesive side 18 and a non-adhesive side 20. The adhesive tape platform 12 can be dispensed from the roll 16 in the same way as any conventional packing tape, shipping tape, or duct tape. For example, the adhesive tape platform 12 may be dispensed from the roll 16 by hand, laid across the seam where the two top flaps of the asset 10 meet, and cut to a suitable length either by hand or using a cutting instrument (e.g., scissors or an automated or manual tape dispenser). Examples of such tapes include tapes having non-adhesive sides 20 that carry one or more coatings or layers (e.g., colored, light reflective, light absorbing, and/or light emitting coatings or layers).

Referring to FIG. 1B, in some examples, the non-adhesive side 20 of the length 13 of the adhesive tape platform 12 includes writing or other markings that convey instructions, warnings, or other information to a person or machine (e.g., a bar code reader), or may simply be decorative and/or entertaining. For example, different types of adhesive tape platforms may be marked with distinctive colorations to distinguish one type of adhesive tape platform from another. In the illustrated example, the length 13 of the adhesive tape platform 12 includes a two-dimensional bar code (e.g., a QR Code) 22, written instructions 24 (i.e., “Cut Here”), and an associated cut line 26 that indicates where the user should cut the adhesive tape platform 12. The written instructions 24 and the cut line 26 typically are printed or otherwise marked on the top non-adhesive surface 20 of the adhesive tape platform 12 during manufacture. The two-dimensional bar code 22, on the other hand, may be marked on the non-adhesive surface 20 of the adhesive tape platform 12 during the manufacture of the adhesive product 12 or, alternatively, may be marked on the non-adhesive surface 20 of the adhesive tape platform 12 as needed using, for example, a printer or other marking device.

In order to avoid damage to the functionality of the segments of the adhesive tape platform 12, the cut lines 26 typically demarcate the boundaries between adjacent segments at locations that are free of any active components of the wireless transducing circuit 14. The spacing between the wireless transducing circuit components 14 and the cut lines 26 may vary depending on the intended communication, transducing and/or adhesive taping application. In the example illustrated in FIG. 1A, the length of the adhesive tape platform 12 that is dispensed to seal the asset 10 corresponds to a single segment of the adhesive tape platform 12. In other examples, the length of the adhesive tape platform 12 needed to seal a asset or otherwise serve the adhesive function for which the adhesive tape platform 12 is being applied may include multiple segments 13 of the adhesive tape platform 12, one or more of which segments 13 may be activated upon cutting the length of the adhesive tape platform 12 from the roll 16 and/or applying the length of the adhesive tape platform to the asset 10.

In some examples, the transducing components 14 that are embedded in one or more segments 13 of the adhesive tape platform 12 are activated when the adhesive tape platform 12 is cut along the cut line 26. In these examples, the adhesive tape platform 12 includes one or more embedded energy sources (e.g., thin film batteries, which may be printed, or conventional cell batteries, such as conventional watch style batteries, rechargeable batteries, or other energy storage device, such as a super capacitor or charge pump) that supply power to the transducing components 14 in one or more segments of the adhesive tape platform 12 in response to being separated from the adhesive tape platform 12 (e.g., along the cut line 26).

In some examples, each segment 13 of the adhesive tape platform 12 includes its own respective energy source including energy harvesting elements that can harvest energy from the environment. In some of these examples, each energy source is configured to only supply power to the components in its respective adhesive tape platform segment regardless of the number of contiguous segments 13 that are in a given length of the adhesive tape platform 12. In other examples, when a given length of the adhesive tape platform 12 includes multiple segments 13, the energy sources in the respective segments 13 are configured to supply power to the transducing components 14 in all of the segments 13 in the given length of the adhesive tape platform 12. In some of these examples, the energy sources are connected in parallel and concurrently activated to power the transducing components 14 in all of the segments 13 at the same time. In other examples, the energy sources are connected in parallel and alternately activated to power the transducing components 14 in respective ones of the adhesive tape platform segments 13 at different time periods, which may or may not overlap.

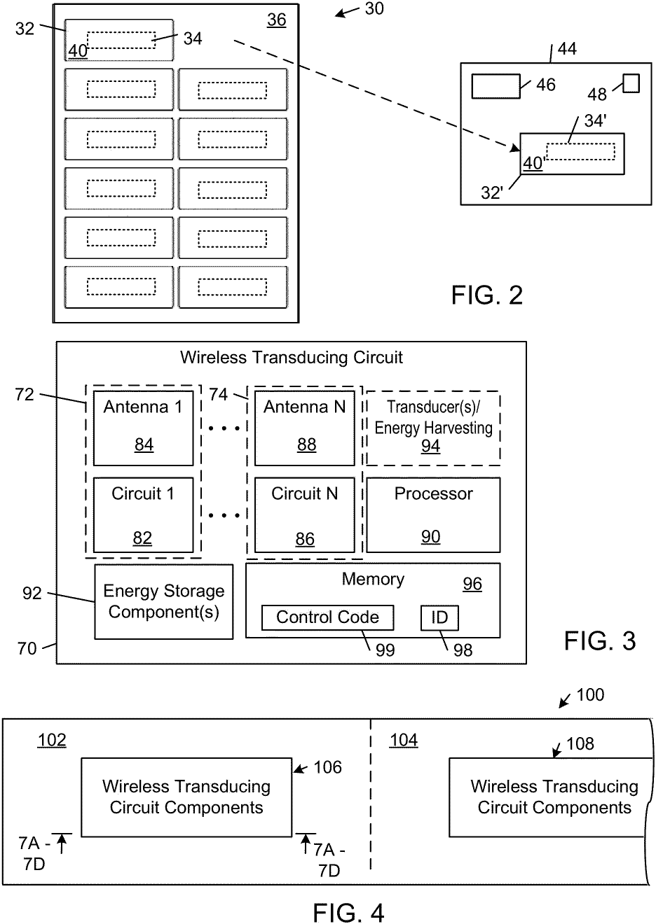

FIG. 2 shows an example adhesive tape platform 30 that includes a set of adhesive tape platform segments 32 each of which includes a respective set of embedded wireless transducing circuit components 34, and a backing sheet 36 with a release coating that prevents the adhesive segments 32 from adhering strongly to the backing sheet 36. Each adhesive tape platform segment 32 includes an adhesive side facing the backing sheet 36, and an opposing non-adhesive side 40. In this example, a particular segment 32′ of the adhesive tape platform 30 has been removed from the backing sheet 36 and affixed to an envelope 44. Each segment 32 of the adhesive tape platform 30 can be removed from the backing sheet 36 in the same way that adhesive labels can be removed from a conventional sheet of adhesive labels (e.g., by manually peeling a segment 32 from the backing sheet 36). In general, the non-adhesive side 40′ of the segment 32′ may include any type of writing, markings, decorative designs, or other ornamentation. In the illustrated example, the non-adhesive side 40′ of the segment 32′ includes writing or other markings that correspond to a destination address for the envelope 44. The envelope 44 also includes a return address 46 and, optionally, a postage stamp or mark 48.

In some examples, segments of the adhesive tape platform 12 are deployed by a human operator. The human operator may be equipped with a mobile phone or other device that allows the operator to authenticate and initialize the adhesive tape platform 12. In addition, the operator can take a picture of a asset including the adhesive tape platform and any barcodes associated with the asset and, thereby, create a persistent record that links the adhesive tape platform 12 to the asset. In addition, the human operator typically will send the picture to a network service and/or transmit the picture to the adhesive tape platform 12 for storage in a memory component of the adhesive tape platform 12.

In some examples, the wireless transducing circuit components 34 that are embedded in a segment 32 of the adhesive tape platform 12 are activated when the segment 32 is removed from the backing sheet 32. In some of these examples, each segment 32 includes an embedded capacitive sensing system that can sense a change in capacitance when the segment 32 is removed from the backing sheet 36. As explained in detail below, a segment 32 of the adhesive tape platform 30 includes one or more embedded energy sources (e.g., thin film batteries, common disk-shaped cell batteries, or rechargeable batteries or other energy storage devices, such as a super capacitor or charge pump) that can be configured to supply power to the wireless transducing circuit components 34 in the segment 32 in response to the detection of a change in capacitance between the segment 32 and the backing sheet 36 as a result of removing the segment 32 from the backing sheet 36.

FIG. 3 shows a block diagram of the components of an example wireless transducing circuit 70 that includes a number of communication systems 72, 74. Example communication systems 72, 74 include a GPS system that includes a GPS receiver circuit 82 (e.g., a receiver integrated circuit) and a GPS antenna 84, and one or more wireless communication systems each of which includes a respective transceiver circuit 86 (e.g., a transceiver integrated circuit) and a respective antenna 88. Example wireless communication systems include a cellular communication system (e.g., GSM/GPRS), a Wi-Fi communication system, an RF communication system (e.g., LoRa), a Bluetooth communication system (e.g., a Bluetooth Low Energy system), a Z-wave communication system, and a ZigBee communication system. The wireless transducing circuit 70 also includes a processor 90 (e.g., a microcontroller or microprocessor), one or more energy storage devices 92 (e.g., non-rechargeable or rechargeable printed flexible battery, conventional single or multiple cell battery, and/or a super capacitor or charge pump), one or more transducers 94 (e.g., sensors and/or actuators, and, optionally, one or more energy harvesting transducer components). In some examples, the conventional single or multiple cell battery may be a watch style disk or button cell battery that is associated electrical connection apparatus (e.g., a metal clip) that electrically connects the electrodes of the battery to contact pads on the flexible circuit 116.

Examples of sensing transducers 94 include a capacitive sensor, an altimeter, a gyroscope, an accelerometer, a temperature sensor, a strain sensor, a pressure sensor, a piezoelectric sensor, a weight sensor, an optical or light sensor (e.g., a photodiode or a camera), an acoustic or sound sensor (e.g., a microphone), a smoke detector, a radioactivity sensor, a chemical sensor (e.g., an explosives detector), a biosensor (e.g., a blood glucose biosensor, odor detectors, antibody based pathogen, food, and water contaminant and toxin detectors, DNA detectors, microbial detectors, pregnancy detectors, and ozone detectors), a magnetic sensor, an electromagnetic field sensor, and a humidity sensor. Examples of actuating (e.g., energy emitting) transducers 94 include light emitting components (e.g., light emitting diodes and displays), electro-acoustic transducers (e.g., audio speakers), electric motors, and thermal radiators (e.g., an electrical resistor or a thermoelectric cooler).

In some examples, the wireless transducing circuit 70 includes a memory 96 for storing data, including, e.g., profile data, state data, event data, sensor data, localization data, security data, and one or more unique identifiers (ID) 98 associated with the wireless transducing circuit 70, such as a product ID, a type ID, and a media access control (MAC) ID, and control code 99. In some examples, the memory 96 may be incorporated into one or more of the processor 90 or transducers 94, or may be a separate component that is integrated in the wireless transducing circuit 70 as shown in FIG. 3. The control code typically is implemented as programmatic functions or program modules that control the operation of the wireless transducing circuit 70, including a tape node communication manager that manages the manner and timing of tape node communications, a tape node power manager that manages power consumption, and a tape node connection manager that controls whether connections with other tape nodes are secure connections or unsecure connections, and a tape node storage manager that securely manages the local data storage on the node. The tape node connection manager ensures the level of security required by the end application and supports various encryption mechanisms. The tape node power manager and tape communication manager work together to optimize the battery consumption for data communication. In some examples, execution of the control code by the different types of tape nodes described herein may result in the performance of similar or different functions.

FIG. 4 is a top view of a portion of an example flexible adhesive tape platform 100 that shows a first segment 102 and a portion of a second segment 104. Each segment 102, 104 of the flexible adhesive tape platform 100 includes a respective set 106, 108 of the components of the wireless transducing circuit 70. The segments 102, 104 and their respective sets of components 106, 108 typically are identical and configured in the same way. In some other embodiments, however, the segments 102, 104 and/or their respective sets of components 106, 108 are different and/or configured in different ways. For example, in some examples, different sets of the segments of the flexible adhesive tape platform 100 have different sets or configurations of tracking and/or transducing components that are designed and/or optimized for different applications, or different sets of segments of the flexible adhesive tape platform may have different ornamentations (e.g., markings on the exterior surface of the platform) and/or different (e.g., alternating) lengths.

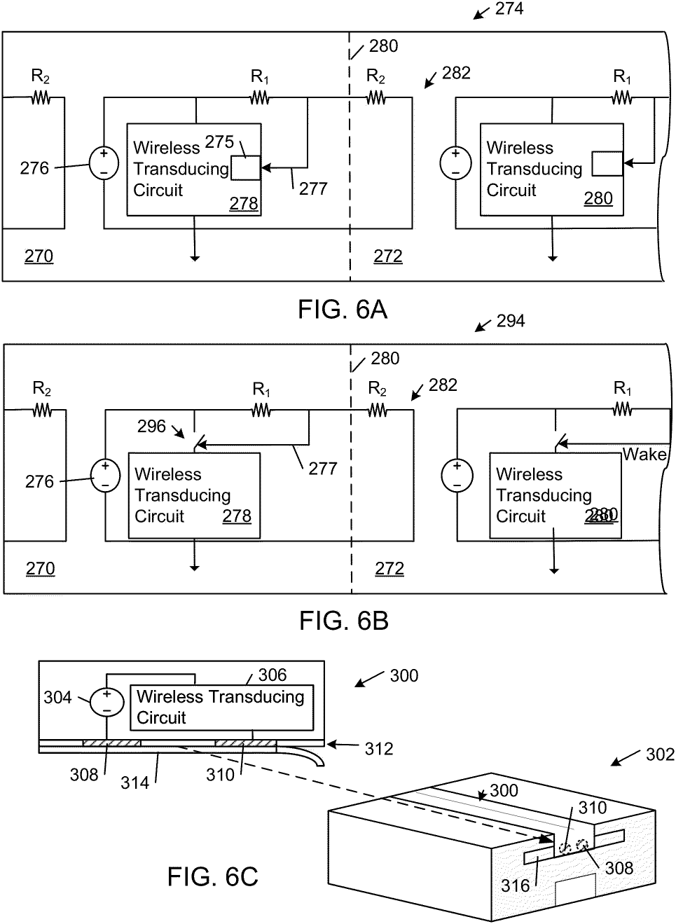

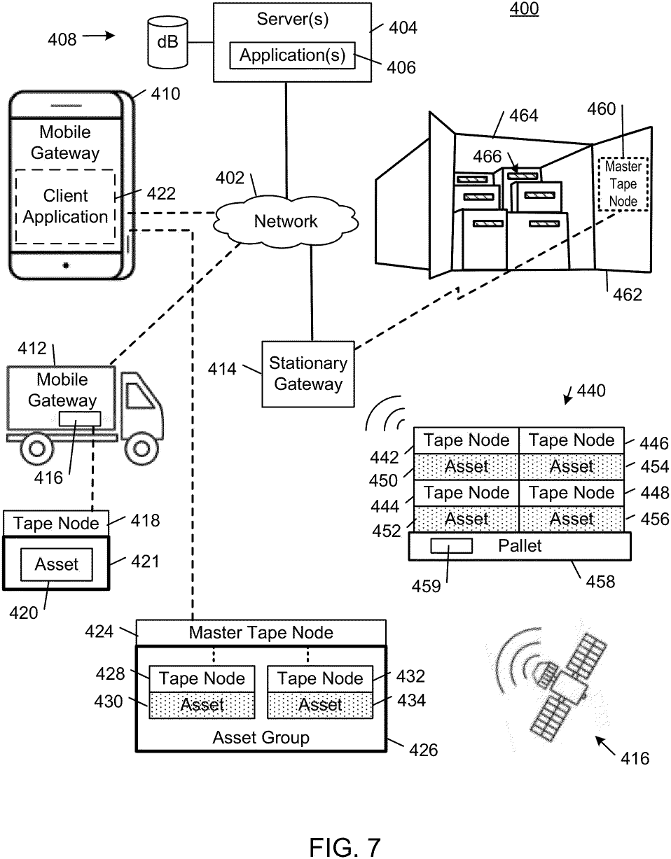

An example method of fabricating the adhesive tape platform 100 (see FIG. 4) according to a roll-to-roll fabrication process is described in connection with FIGS. 6, 7A, and 7B of U.S. Pat. No. 10,262,255, issued Apr. 16, 2019, the entirety of which is incorporated herein by reference.

The instant specification describes an example system of adhesive tape platforms (also referred to herein as “tape nodes”) that can be used to implement a low-cost wireless network infrastructure for performing monitoring, tracking, and other asset management functions relating to, for example, parcels, persons, tools, equipment and other physical assets and objects. The example system includes a set of three different types of tape nodes that have different respective functionalities and different respective cover markings that visually distinguish the different tape node types from one another. In one non-limiting example, the covers of the different tape node types are marked with different colors (e.g., white, green, and black). In the illustrated examples, the different tape node types are distinguishable from one another by their respective wireless communications capabilities and their respective sensing capabilities.

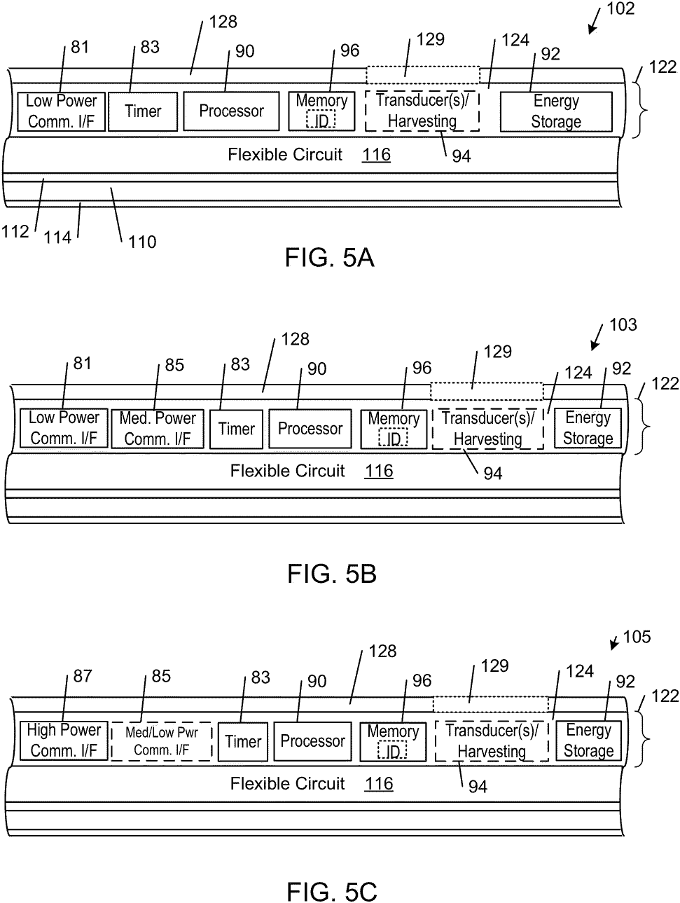

FIG. 5A shows a cross-sectional side view of a portion of an example segment 102 of the flexible adhesive tape platform 100 that includes a respective set of the components of the wireless transducing circuit 106 corresponding to the first tape node type (i.e., white). The flexible adhesive tape platform segment 102 includes an adhesive layer 112, an optional flexible substrate 110, and an optional adhesive layer 114 on the bottom surface of the flexible substrate 110. If the bottom adhesive layer 114 is present, a release liner (not shown) may be (weakly) adhered to the bottom surface of the adhesive layer 114. In some examples, the adhesive layer 114 includes an adhesive (e.g., an acrylic foam adhesive) that has a high bond strength that is sufficient to prevent removal of the adhesive segment 102 from a surface on which the adhesive layer 114 is adhered without destroying the physical or mechanical integrity of the adhesive segment 102 and/or one or more of its constituent components. In some examples, the optional flexible substrate 110 is implemented as a prefabricated adhesive tape that includes the adhesive layers 112, 114 and the optional release liner. In other examples, the adhesive layers 112, 114 are applied to the top and bottom surfaces of the flexible substrate 110 during the fabrication of the adhesive tape platform 100. The adhesive layer 112 bonds the flexible substrate 110 to a bottom surface of a flexible circuit 116, that includes one or more wiring layers (not shown) that connect the processor 90, a low power wireless communication interface 81 (e.g., a Zigbee, Bluetooth® Low Energy (BLE) interface, or other low power communication interface), a timer circuit 83, transducing and/or energy harvesting component(s) 94 (if present), the memory 96, and other components in a device layer 122 to each other and to the energy storage component 92 and, thereby, enable the transducing, tracking and other functionalities of the flexible adhesive tape platform segment 102. The low power wireless communication interface 81 typically includes one or more of the antennas 84, 88 and one or more of the wireless circuits 82, 86.

FIG. 5B shows a cross-sectional side view of a portion of an example segment 103 of the flexible adhesive tape platform 100 that includes a respective set of the components of the wireless transducing circuit 106 corresponding to the second tape node type (i.e., green). In this example, the flexible adhesive tape platform segment 103 differs from the segment 102 shown in FIG. 5A by the inclusion of a medium power communication interface 85 (e.g., a LoRa interface) in addition to the low power communications interface that is present in the first tape node type (i.e., white). The medium power communication interface has longer communication range than the low power communication interface. In some examples, one or more other components of the flexible adhesive tape platform segment 103 differ, for example, in functionality or capacity (e.g., larger energy source).

FIG. 5C shows a cross-sectional side view of a portion of an example segment 105 of the flexible adhesive tape platform 100 that includes a respective set of the components of the wireless transducing circuit 106 corresponding to the third tape node type (i.e., black). In this example, the flexible adhesive tape platform segment 105 includes a high power communications interface 87 (e.g., a cellular interface; e.g., GSM/GPRS) and an optional medium and/or low power communications interface 85. The high power communication range provides global coverage to available infrastructure (e.g. the cellular network). In some examples, one or more other components of the flexible adhesive tape platform segment 105 differ, for example, in functionality or capacity (e.g., larger energy source).

FIGS. 5A-5C show examples in which the cover layer 128 of the flexible adhesive tape platform 100 includes one or more interfacial regions 129 positioned over one or more of the transducers 94. In examples, one or more of the interfacial regions 129 have features, properties, compositions, dimensions, and/or characteristics that are designed to improve the operating performance of the platform 100 for specific applications. In some examples, the flexible adhesive tape platform 100 includes multiple interfacial regions 129 over respective transducers 94, which may be the same or different depending on the target applications. Example interfacial regions include an opening, an optically transparent window, and/or a membrane located in the interfacial region 129 of the cover 128 that is positioned over the one or more transducers and/or energy harvesting components 94. Additional details regarding the structure and operation of example interfacial regions 129 are described in U.S. Provisional Pat. Application No. 62/680716, filed Jun. 5, 2018, PCT Patent Application No. PCT/US2018/064919, filed Dec. 11, 2018, U.S. Pat. No. 10,885,420, issued Jan. 4, 2021, U.S. Pat. No. 10,902,310 issued Jan. 25, 2021, and US Provisional Pat. Application No. 62/670712, filed May 11, 2018, all of which are incorporated herein in their entirety.

In some examples, a flexible polymer layer 124 encapsulates the device layer 122 and thereby reduces the risk of damage that may result from the intrusion of contaminants and/or liquids (e.g., water) into the device layer 122. The flexible polymer layer 124 also planarizes the device layer 122. This facilitates optional stacking of additional layers on the device layer 122 and also distributes forces generated in, on, or across the adhesive tape platform segment 102 so as to reduce potentially damaging asymmetric stresses that might be caused by the application of bending, torqueing, pressing, or other forces that may be applied to the flexible adhesive tape platform segment 102 during use. In the illustrated example, a flexible cover 128 is bonded to the planarizing polymer 124 by an adhesive layer (not shown).

The flexible cover 128 and the flexible substrate 110 may have the same or different compositions depending on the intended application. In some examples, one or both of the flexible cover 128 and the flexible substrate 110 include flexible film layers and/or paper substrates, where the film layers may have reflective surfaces or reflective surface coatings. Example compositions for the flexible film layers include polymer films, such as polyester, polyimide, polyethylene terephthalate (PET), and other plastics. The optional adhesive layer on the bottom surface of the flexible cover 128 and the adhesive layers 112, 114 on the top and bottom surfaces of the flexible substrate 110 typically include a pressure-sensitive adhesive (e.g., a silicon-based adhesive). In some examples, the adhesive layers are applied to the flexible cover 128 and the flexible substrate 110 during manufacture of the adhesive tape platform 100 (e.g., during a roll-to-roll or sheet-to-sheet fabrication process). In other examples, the flexible cover 128 may be implemented by a prefabricated single-sided pressure-sensitive adhesive tape and the flexible substrate 110 may be implemented by a prefabricated double-sided pressure-sensitive adhesive tape; both kinds of tape may be readily incorporated into a roll-to-roll or sheet-to-sheet fabrication process. In some examples, the flexible polymer layer 124 is composed of a flexible epoxy (e.g., silicone).

In some examples, the energy storage device 92 is a flexible battery that includes a printed electrochemical cell, which includes a planar arrangement of an anode and a cathode and battery contact pads. In some examples, the flexible battery may include lithium-ion cells or nickel-cadmium electro-chemical cells. The flexible battery typically is formed by a process that includes printing or laminating the electro-chemical cells on a flexible substrate (e.g., a polymer film layer). In some examples, other components may be integrated on the same substrate as the flexible battery. For example, the low power wireless communication interface 81 and/or the processor(s) 90 may be integrated on the flexible battery substrate. In some examples, one or more of such components also (e.g., the flexible antennas and the flexible interconnect circuits) may be printed on the flexible battery substrate.

In some examples, the flexible circuit 116 is formed on a flexible substrate by printing, etching, or laminating circuit patterns on the flexible substrate. In some examples, the flexible circuit 116 is implemented by one or more of a single-sided flex circuit, a double access or back bared flex circuit, a sculpted flex circuit, a double-sided flex circuit, a multi-layer flex circuit, a rigid flex circuit, and a polymer thick film flex circuit. A single-sided flexible circuit has a single conductor layer made of, for example, a metal or conductive (e.g., metal filled) polymer on a flexible dielectric film. A double access or back bared flexible circuit has a single conductor layer but is processed so as to allow access to selected features of the conductor pattern from both sides. A sculpted flex circuit is formed using a multistep etching process that produces a flex circuit that has finished copper conductors that vary in thickness along their respective lengths. A multilayer flex circuit has three of more layers of conductors, where the layers typically are interconnected using plated through holes. Rigid flex circuits are a hybrid construction of flex circuit consisting of rigid and flexible substrates that are laminated together into a single structure, where the layers typically are electrically interconnected via plated through holes. In polymer thick film (PTF) flex circuits, the circuit conductors are printed onto a polymer base film, where there may be a single conductor layer or multiple conductor layers that are insulated from one another by respective printed insulating layers.

In the example flexible adhesive tape platform segments 102 shown in FIGS. 5A-5C, the flexible circuit 116 is a single access flex circuit that interconnects the components of the adhesive tape platform on a single side of the flexible circuit 116. In other examples, the flexible circuit 116 is a double access flex circuit that includes a front-side conductive pattern that interconnects the low power communications interface 81, the timer circuit 83, the processor 90, the one or more transducers 94 (if present), and the memory 96, and allows through-hole access (not shown) to a back-side conductive pattern that is connected to the flexible battery (not shown). In these examples, the front-side conductive pattern of the flexible circuit 116 connects the communications circuits 82, 86 (e.g., receivers, transmitters, and transceivers) to their respective antennas 84, 88 and to the processor 90, and also connects the processor 90 to the one or more sensors 94 and the memory 96. The backside conductive pattern connects the active electronics (e.g., the processor 90, the communications circuits 82, 86, and the transducers) on the front-side of the flexible circuit 116 to the electrodes of the flexible battery 116 via one or more through holes in the substrate of the flexible circuit 116.

Depending on the target application, the wireless transducing circuits 70 are distributed across the flexible adhesive tape platform 100 according to a specified sampling density, which is the number of wireless transducing circuits 70 for a given unit size (e.g., length or area) of the flexible adhesive tape platform 100. In some examples, a set of multiple flexible adhesive tape platforms 100 are provided that include different respective sampling densities in order to seal different asset sizes with a desired number of wireless transducing circuits 70. In particular, the number of wireless transducing circuits per asset size is given by the product of the sampling density specified for the adhesive tape platform and the respective size of the adhesive tape platform 100 needed to seal the asset. This allows an automated packaging system to select the appropriate type of flexible adhesive tape platform 100 to use for sealing a given asset with the desired redundancy (if any) in the number of wireless transducer circuits 70. In some example applications (e.g., shipping low value goods), only one wireless transducing circuit 70 is used per asset, whereas in other applications (e.g., shipping high value goods) multiple wireless transducing circuits 70 are used per asset. Thus, a flexible adhesive tape platform 100 with a lower sampling density of wireless transducing circuits 70 can be used for the former application, and a flexible adhesive tape platform 100 with a higher sampling density of wireless transducing circuits 70 can be used for the latter application. In some examples, the flexible adhesive tape platforms 100 are color-coded or otherwise marked to indicate the respective sampling densities with which the wireless transducing circuits 70 are distributed across the different types of adhesive tape platforms 100.

Referring to FIG. 6A, in some examples, each of one or more of the segments 270, 272 of a flexible adhesive tape platform 274 includes a respective one-time wake circuit 275 that delivers power from the respective energy source 276 to the respective wireless circuit 278 (e.g., a processor, one or more transducers, and one or more wireless communications circuits) in response to an event. In some of these examples, the wake circuit 275 is configured to transition from an off state to an on state when the voltage on the wake node 277 exceeds a threshold level, at which point the wake circuit transitions to an on state to power-on the segment 270. In the illustrated example, this occurs when the user separates the segment from the adhesive tape platform 274, for example, by cutting across the adhesive tape platform 274 at a designated location (e.g., along a designated cut-line 280). In particular, in its initial, un-cut state, a minimal amount of current flows through the resistors R1 and R2. As a result, the voltage on the wake node 277 remains below the threshold turn-on level. After the user cuts across the adhesive tape platform 274 along the designated cut-line 280, the user creates an open circuit in the loop 282, which pulls the voltage of the wake node above the threshold level and turns on the wake circuit 275. As a result, the voltage across the energy source 276 will appear across the wireless circuit 278 and, thereby, turn on the segment 270. In particular embodiments, the resistance value of resistor R1 is greater than the resistance value of R2. In some examples, the resistance values of resistors R1 and R2 are selected based on the overall design of the adhesive product system (e.g., the target wake voltage level and a target leakage current).

In some examples, each of one or more of the segments of an adhesive tape platform includes a respective sensor and a respective wake circuit that delivers power from the respective energy source to the respective one or more of the respective wireless circuit components 278 in response to an output of the sensor. In some examples, the respective sensor is a strain sensor that produces a wake signal based on a change in strain in the respective segment. In some of these examples, the strain sensor is affixed to a adhesive tape platform and configured to detect the stretching of the tracking adhesive tape platform segment as the segment is being peeled off a roll or a sheet of the adhesive tape platform. In some examples, the respective sensor is a capacitive sensor that produces a wake signal based on a change in capacitance in the respective segment. In some of these examples, the capacitive sensor is affixed to an adhesive tape platform and configured to detect the separation of the tracking adhesive tape platform segment from a roll or a sheet of the adhesive tape platform. In some examples, the respective sensor is a flex sensor that produces a wake signal based on a change in curvature in the respective segment. In some of these examples, the flex sensor is affixed to a adhesive tape platform and configured to detect bending of the tracking adhesive tape platform segment as the segment is being peeled off a roll or a sheet of the adhesive tape platform. In some examples, the respective sensor is a near field communications sensor that produces a wake signal based on a change in inductance in the respective segment.

FIG. 6B shows another example of an adhesive tape platform 294 that delivers power from the respective energy source 276 to the respective tracking circuit 278 (e.g., a processor, one or more transducers, and one or more wireless communications circuits) in response to an event. This example is similar in structure and operation as the adhesive tape platform 294 shown in FIG. 6A, except that the wake circuit 275 is implemented by a switch 296 that is configured to transition from an open state to a closed state when the voltage on the switch node 277 exceeds a threshold level. In the initial state of the adhesive tape platform 294, the voltage on the switch node is below the threshold level as a result of the low current level flowing through the resistors R1 and R2. After the user cuts across the adhesive tape platform 294 along the designated cut-line 280, the user creates an open circuit in the loop 282, which pulls up the voltage on the switch node above the threshold level to close the switch 296 and turn on the wireless circuit 278.

FIG. 6C shows a diagrammatic cross-sectional front view of an example adhesive tape platform 300 and a perspective view of an example asset 302. Instead of activating the adhesive tape platform in response to separating a segment of the adhesive tape platform from a roll or a sheet of the adhesive tape platform, this example is configured to supply power from the energy source 302 to turn on the wireless transducing circuit 306 in response to establishing an electrical connection between two power terminals 308, 310 that are integrated into the adhesive tape platform. In particular, each segment of the adhesive tape platform 300 includes a respective set of embedded tracking components, an adhesive layer 312, and an optional backing sheet 314 with a release coating that prevents the segments from adhering strongly to the backing sheet 314. In some examples, the power terminals 308, 310 are composed of an electrically conductive material (e.g., a metal, such as copper) that may be printed or otherwise patterned and/or deposited on the backside of the adhesive tape platform 300. In operation, the adhesive tape platform can be activated by removing the backing sheet 314 and applying the exposed adhesive layer 312 to a surface that includes an electrically conductive region 316. In the illustrated embodiment, the electrically conductive region 316 is disposed on a portion of the asset 302. When the adhesive backside of the adhesive tape platform 300 is adhered to the asset with the exposed terminals 308, 310 aligned and in contact with the electrically conductive region 316 on the asset 302, an electrical connection is created through the electrically conductive region 316 between the exposed terminals 308, 310 that completes the circuit and turns on the wireless transducing circuit 306. In particular embodiments, the power terminals 308, 310 are electrically connected to any respective nodes of the wireless transducing circuit 306 that would result in the activation of the tracking circuit 306 in response to the creation of an electrical connection between the power terminals 308, 310.

In some examples, after a tape node is turned on, it will communicate with the network service to confirm that the user/operator who is associated with the tape node is an authorized user who has authenticated himself or herself to the network service 54. In these examples, if the tape node cannot confirm that the user/operator is an authorized user, the tape node will turn itself off.

### Deployment of Tape Nodes

FIG. 7 shows an example network communications environment 400 (also referred to herein as an “IOT system” 400 or “tracking system” 400) that includes a network 402 that supports communications between one or more servers 404 executing one or more applications of a network service 408, mobile gateways 410, 412, a stationary gateway 414, and various types of tape nodes that are associated with various assets (e.g., parcels, equipment, tools, persons, and other things). Each member of the IOT system 400 may be referred to as a node of the IOT system 400, including the tape nodes, other wireless IOT devices, gateways (stationary and mobile), client devices, and servers. In some examples, the network 402 includes one or more network communication systems and technologies, including any one or more of wide area networks, local area networks, public networks (e.g., the internet), private networks (e.g., intranets and extranets), wired networks, and wireless networks. For example, the network 402 includes communications infrastructure equipment, such as a geolocation satellite system 416 (e.g., GPS, GLONASS, and NAVSTAR), cellular communication systems (e.g., GSM/GPRS), Wi-Fi communication systems, RF communication systems (e.g., LoRa), Bluetooth communication systems (e.g., a Bluetooth Low Energy system), Z-wave communication systems, and ZigBee communication systems.

In some examples, the one or more network service applications 406 leverage the above-mentioned communications technologies to create a hierarchical wireless network of tape nodes that improves asset management operations by reducing costs and improving efficiency in a wide range of processes, from asset packaging, asset transporting, asset tracking, asset condition monitoring, asset inventorying, and asset security verification. Communication across the network is secured by a variety of different security mechanisms. In the case of existing infrastructure, a communication link the communication uses the infrastructure security mechanisms. In case of communications among tapes nodes, the communication is secured through a custom security mechanism. In certain cases, tape nodes can also be configured to support block chain to protect the transmitted and stored data.

A set of tape nodes can be configured by the network service 408 to create hierarchical communications network. The hierarchy can be defined in terms of one or more factors, including functionality (e.g., wireless transmission range or power), role (e.g., master tape node vs. peripheral tape node), or cost (e.g., a tape node equipped with a cellular transceiver vs. a peripheral tape node equipped with a Bluetooth LE transceiver). Tape nodes can be assigned to different levels of a hierarchical network according to one or more of the above-mentioned factors. For example, the hierarchy can be defined in terms of communication range or power, where tape nodes with higher power or longer communication range transceivers are arranged at a higher level of the hierarchy than tape nodes with lower power or lower range transceivers. In another example, the hierarchy is defined in terms of role, where, e.g., a master tape node is programmed to bridge communications between a designated group of peripheral tape nodes and a gateway node or server node. The problem of finding an optimal hierarchical structure can be formulated as an optimization problem with battery capacity of nodes, power consumption in various modes of operation, desired latency, external environment, etc. and can be solved using modern optimization methods e.g. neural networks, artificial intelligence, and other machine learning computing systems that take expected and historical data to create an optimal solution and can create algorithms for modifying the system’s behavior adaptively in the field.

The tape nodes may be deployed by automated equipment or manually. In this process, a tape node typically is separated from a roll or sheet and adhered to a asset, or other stationary or mobile object (e.g., a structural element of a warehouse, or a vehicle, such as a delivery truck) or stationary object (e.g., a structural element of a building). This process activates the tape node and causes the tape node to communicate with a server 404 of the network service 408. In this process, the tape node may communicate through one or more other tape nodes in the communication hierarchy. In this process, the network server 404 executes the network service application 406 to programmatically configure tape nodes that are deployed in the environment 400. In some examples, there are multiple classes or types of tape nodes, where each tape node class has a different respective set of functionalities and/or capacities.

In some examples, the one or more network service servers 404 communicate over the network 402 with one or more gateways that are configured to send, transmit, forward, or relay messages to the network 402 and activated tape nodes that are associated with respective assets and within communication range. Example gateways include mobile gateways 410, 412 and a stationary gateway 414. In some examples, the mobile gateways 410, 412, and the stationary gateway 414 are able to communicate with the network 402 and with designated sets or groups of tape nodes.

In some examples, the mobile gateway 412 is a vehicle (e.g., a delivery truck or other mobile hub) that includes a wireless communications unit 416 that is configured by the network service 408 to communicate with a designated set of tape nodes, including a peripheral tape node 418 in the form of a label that is adhered to an asset 420 contained within a parcel 421 (e.g., an envelope), and is further configured to communicate with the network service 408 over the network 402. In some examples, the peripheral tape node 418 includes a lower power wireless communications interface of the type used in, e.g., tape node 102 (shown in FIG. 5A), and the wireless communications unit 416 is implemented by a tape node (e.g., one of tape node 103 or tape node 105, respectively shown in FIGS. 5B and 5C) that includes a lower power communications interface for communicating with tape nodes within range of the mobile gateway 412 and a higher power communications interface for communicating with the network 402. In this way, the tape nodes 418 and 416 create a hierarchical wireless network of nodes for transmitting, forwarding, bridging, relaying, or otherwise communicating wireless messages to, between, or on behalf of the peripheral tape node 418 and the network service 408 in a power-efficient and cost-effective way.

In some examples, the mobile gateway 410 is a mobile phone that is operated by a human operator and executes a client application 422 that is configured by the network service 408 to communicate with a designated set of tape nodes, including a master tape node 424 that is adhered to a parcel 426 (e.g., a box), and is further configured to communicate with the network service 408 over the network 402. In the illustrated example, the parcel 426 contains a first parcel labeled or sealed by a tape node 428 and containing a first asset 430, and a second parcel labeled or sealed by a tape node 432 and containing a second asset 434. As explained in detail below, the master tape node 424 communicates with each of the peripheral tape nodes 428, 432 and communicates with the mobile gateway 408 in accordance with a hierarchical wireless network of tape nodes. In some examples, each of the peripheral tape nodes 428, 432 includes a lower power wireless communications interface of the type used in, e.g., tape node 102 (shown in FIG. 5A), and the master tape node 424 is implemented by a tape node (e.g., tape node 103, shown in FIG. 5B) that includes a lower power communications interface for communicating with the peripheral tape nodes 428, 432 contained within the parcel 426, and a higher power communications interface for communicating with the mobile gateway 410. The master tape node 424 is operable to relay wireless communications between the tape nodes 428, 432 contained within the parcel 426 and the mobile gateway 410, and the mobile gateway 410 is operable to relay wireless communications between the master tape node 424 and the network service 408 over the wireless network 402. In this way, the master tape node 424 and the peripheral tape nodes 428 and 432 create a hierarchical wireless network of nodes for transmitting, forwarding, relaying, or otherwise communicating wireless messages to, between, or on behalf of the peripheral tape nodes 428, 432 and the network service 408 in a power-efficient and cost-effective way.

In some examples, the stationary gateway 414 is implemented by a server executing a server application that is configured by the network service 408 to communicate with a designated set 440 of tape nodes 442, 444, 446, 448 that are adhered to respective parcels containing respective assets 450, 452, 454, 456 on a pallet 458. In other examples, the stationary gateway 414 is implemented by a tape node (e.g., one of tape node 103 or tape node 105, respectively shown in FIGS. 5B and 5C) that is adhered to, for example, a wall, column or other infrastructure component of the environment 400, and includes a lower power communications interface for communicating with tape nodes within range of the stationary gateway 414 and a higher power communications interface for communicating with the network 402. In one embodiment, each of the tape nodes 442-448 is a peripheral tape node and is configured by the network service 408 to communicate individually with the stationary gateway 414, which relays communications from the tape nodes 442-448 to the network service 408 through the stationary gateway 414 and over the communications network 402. In another embodiment, one of the tape nodes 442-448 at a time is configured as a master tape node that transmits, forwards, relays, or otherwise communicate wireless messages to, between, or on behalf of the other tape nodes on the pallet 458. In this embodiment, the master tape node may be determined by the tape nodes 442-448 or designated by the network service 408. In some examples, the tape node with the longest range or highest remaining power level is determined to be the master tape node. In some examples, when the power level of the current master tape node drops below a certain level (e.g., a fixed power threshold level or a threshold level relative to the power levels of one or more of the other tape nodes), another one of the tape nodes assumes the role of the master tape node. In some examples, a master tape node 459 is adhered to the pallet 458 and is configured to perform the role of a master node for the tape nodes 442-448. In these ways, the tape nodes 442-448, 458 are configurable to create different hierarchical wireless networks of nodes for transmitting, forwarding, relaying, bridging, or otherwise communicating wireless messages with the network service 408 through the stationary gateway 414 and over the network 402 in a power-efficient and cost-effective way.

In the illustrated example, the stationary gateway 414 also is configured by the network service 408 to communicate with a designated set of tape nodes, including a master tape node 460 that is adhered to the inside of a door 462 of a shipping container 464, and is further configured to communicate with the network service 408 over the network 402. In the illustrated example, the shipping container 464 contains a number of parcels labeled or sealed by respective peripheral tape nodes 466 and containing respective assets. The master tape node 416 communicates with each of the peripheral tape nodes 466 and communicates with the stationary gateway 415 in accordance with a hierarchical wireless network of tape nodes. In some examples, each of the peripheral tape nodes 466 includes a lower power wireless communications interface of the type used in, e.g., tape node 102 (shown in FIG. 5A), and the master tape node 460 is implemented by a tape node (e.g., tape node 103, shown in FIG. 5B) that includes a lower power communications interface for communicating with the peripheral tape nodes 466 contained within the shipping container 464, and a higher power communications interface for communicating with the stationary gateway 414.

In some examples, when the doors of the shipping container 464 are closed, the master tape node 460 is operable to communicate wirelessly with the peripheral tape nodes 466 contained within the shipping container 464. In an example, the master tape node 460 is configured to collect sensor data from the peripheral tape nodes and, in some embodiments, process the collected data to generate, for example, one or more histograms from the collected data. When the doors of the shipping container 464 are open, the master tape node 460 is programmed to detect the door opening (e.g., with an accelerometer component of the master tape node 460) and, in addition to reporting the door opening event to the network service 408, the master tape node 460 is further programmed to transmit the collected data and/or the processed data in one or more wireless messages to the stationary gateway 414. The stationary gateway 414, in turn, is operable to transmit the wireless messages received from the master tape node 460 to the network service 408 over the wireless network 402. Alternatively, in some examples, the stationary gateway 414 also is operable to perform operations on the data received from the master tape node 460 with the same type of data produced by the master node 459 based on sensor data collected from the tape nodes 442-448. In this way, the master tape node 460 and the peripheral tape nodes 466 create a hierarchical wireless network of nodes for transmitting, forwarding, relaying, or otherwise communicating wireless messages to, between, or on behalf of the peripheral tape nodes 466 and the network service 408 in a power-efficient and cost-effective way.

In an example of the embodiment shown in FIG. 7, there are three classes of tape nodes: a short range tape node, a medium range tape node, and a long range tape node, as respectively shown in FIGS. 5A-5C. The short range tape nodes typically are adhered directly to parcels containing assets. In the illustrated example, the tape nodes 418, 428, 432, 442-448, 466 are short range tape nodes. The short range tape nodes typically communicate with a low power wireless communication protocol (e.g., Bluetooth LE, Zigbee, or Z-wave). The medium range tape nodes typically are adhered to objects (e.g., a box 426 and a shipping container 460) that are associated with multiple parcels that are separated from the medium range tape nodes by a barrier or a large distance. In the illustrated example, the tape nodes 424 and 460 are medium range tape nodes. The medium range tape nodes typically communicate with a medium power wireless communication protocol (e.g., LoRa or Wi-Fi). The long-range tape nodes typically are adhered to mobile or stationary infrastructure of the wireless communication environment 400. In the illustrated example, the mobile gateway tape node 412 and the stationary gateway tape node 414 are long range tape nodes. The long range tape nodes typically communicate with other nodes using a high power wireless communication protocol (e.g., a cellular data communication protocol). In some examples, the mobile gateway tape node 436 is adhered to a mobile vehicle (e.g., a truck). In these examples, the mobile gateway 412 may be moved to different locations in the environment 400 to assist in connecting other tape nodes to the server 404. In some examples, the stationary gateway tape node 414 may be attached to a stationary structure (e.g., a wall) in the environment 400 with a known geographic location. In these examples, other tape nodes in the environment can determine their geographic location by querying the gateway tape node 414.

### Wireless Communications Network

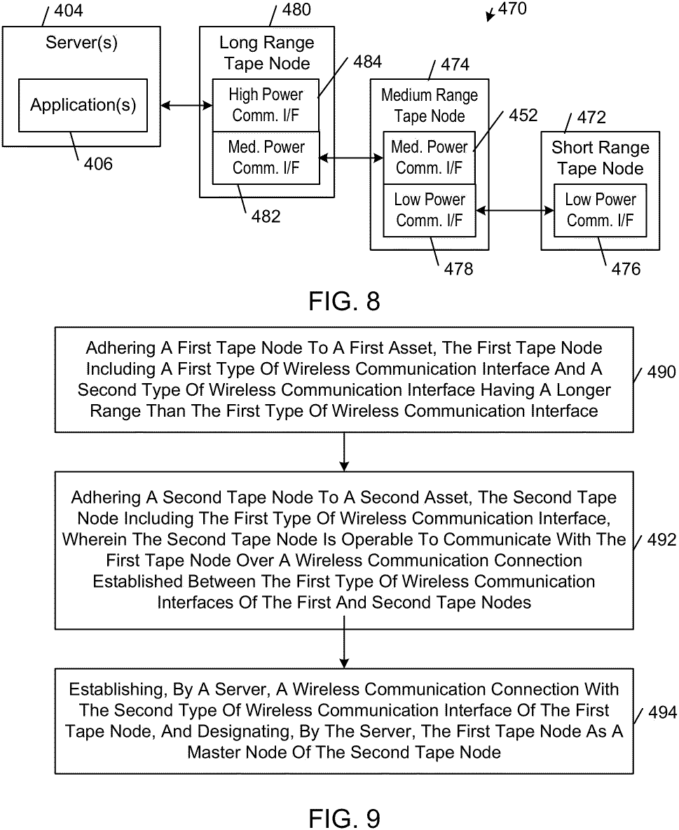

FIG. 8 shows an example hierarchical wireless communications network of tape nodes 470. In this example, the short range tape node 472 and the medium range tape node 474 communicate with one another over their respective low power wireless communication interfaces 476, 478. The medium range tape node 474 and the long range tape node 480 communicate with one another over their respective medium power wireless communication interfaces 478, 482. The long range tape node 480 and the network server 404 communicate with one another over the high power wireless communication interface 484. In some examples, the low power communication interfaces 476, 478 establish wireless communications with one another in accordance with the Bluetooth LE protocol, the medium power communication interfaces 452, 482 establish wireless communications with one another in accordance with the LoRa communications protocol, and the high power communication interface 484 establishes wireless communications with the server 404 in accordance with a cellular communications protocol.

In some examples, the different types of tape nodes are deployed at different levels in the communications hierarchy according to their respective communications ranges, with the long range tape nodes generally at the top of the hierarchy, the medium range tape nodes generally in the middle of the hierarchy, and the short range tape nodes generally at the bottom of the hierarchy. In some examples, the different types of tape nodes are implemented with different feature sets that are associated with component costs and operational costs that vary according to their respective levels in the hierarchy. This allows system administrators flexibility to optimize the deployment of the tape nodes to achieve various objectives, including cost minimization, asset tracking, asset localization, and power conservation.

In some examples, a server 404 of the network service 408 designates a tape node at a higher level in a hierarchical communications network as a master node of a designated set of tape nodes at a lower level in the hierarchical communications network. For example, the designated master tape node may be adhered to a parcel (e.g., a box, pallet, or shipping container) that contains one or more tape nodes that are adhered to one or more assets containing respective assets. In order to conserve power, the tape nodes typically communicate according to a schedule promulgated by the server 404 of the network service 408. The schedule usually dictates all aspects of the communication, including the times when particular tape nodes should communicate, the mode of communication, and the contents of the communication. In one example, the server 404 transmits programmatic Global Scheduling Description Language (GSDL) code to the master tape node and each of the lower-level tape nodes in the designated set. In this example, execution of the GSDL code causes each of the tape nodes in the designated set to connect to the master tape node at a different respective time that is specified in the GSDL code, and to communicate a respective set of one or more data packets of one or more specified types of information over the respective connection. In some examples, the master tape node simply forwards the data packets to the server network node 404, either directly or indirectly through a gateway tape node (e.g., the long range tape node 416 adhered to the mobile vehicle 412 or the long range tape node 414 adhered to an infrastructure component of the environment 400). In other examples, the master tape node processes the information contained in the received data packets and transmits the processed information to the server network node 404.

FIG. 9 shows an example method of creating a hierarchical communications network. In accordance with this method, a first tape node is adhered to a first asset in a set of associated assets, the first tape node including a first type of wireless communication interface and a second type of wireless communication interface having a longer range than the first type of wireless communication interface (FIG. 9, block 490). A second tape node is adhered to a second asset in the set, the second tape node including the first type of wireless communication interface, wherein the second tape node is operable to communicate with the first tape node over a wireless communication connection established between the first type of wireless communication interfaces of the first and second tape nodes (FIG. 9, block 492). An application executing on a computer system (e.g., a server 404 of a network service 408) establishes a wireless communication connection with the second type of wireless communication interface of the first tape node, and the application transmits programmatic code executable by the first tape node to function as a master tape node with respect to the second tape node (FIG. 9, block 494).

In other embodiments, the second tape node is assigned the role of the master node of the first tape node.

### Distributed Agent Operating System

As used herein, the term “node” refers to both a tape node and a non-tape node (i.e., a node or wireless device that is not an adhesive tape platform) unless the node is explicitly designated as a “tape node” or a “non-tape node.” In some embodiments, a non-tape node may have the same or similar communication, sensing, processing and other functionalities and capabilities as the tape nodes described herein, except without being integrated into a tape platform. In some embodiments, non-tape nodes can interact seamlessly with tape nodes. Each node may be assigned a respective unique identifier, according to some embodiments.

The following disclosure describes a distributed software operating system that is implemented by distributed hardware nodes executing intelligent agent software to perform various tasks or algorithms. In some embodiments, the operating system distributes functionalities (e.g., performing analytics on data or statistics collected or generated by nodes) geographically across multiple intelligent agents that are bound to items (e.g., parcels, containers, packages, boxes, pallets, a loading dock, a door, a light switch, a vehicle such as a delivery truck, a shipping facility, a port, a hub, etc.). In addition, the operating system dynamically allocates the hierarchical roles (e.g., master and slave roles) that nodes perform over time in order to improve system performance, such as optimizing battery life across nodes, improving responsiveness, and achieving overall objectives. In some embodiments, optimization is achieved using a simulation environment for optimizing key performance indicators (PKIs).

In some embodiments, the nodes are programmed to operate individually or collectively as autonomous intelligent agents. In some embodiments, nodes are configured to communicate and coordinate actions and respond to events. In some embodiments, a node is characterized by its identity, its mission, and the services that it can provide to other nodes. A node’s identity is defined by its capabilities (e.g., battery life, sensing capabilities, and communications interfaces). A node’s mission (or objective) is defined by the respective program code, instructions, or directives it receives from another node (e.g., a server or a master node) and the actions or tasks that it performs in accordance with that program code, instructions, or directives (e.g., sense temperature every hour and send temperature data to a master node to upload to a server). A node’s services define the functions or tasks that it is permitted to perform for other nodes (e.g., retrieve temperature data from a peripheral node and send the received temperature data to the server). At least for certain tasks, once programmed and configured with their identities, missions, and services, nodes can communicate with one another and request services from and provide services to one another independently of the server.

Thus, in accordance with the runtime operating system every agent knows its objectives (programmed). Every agent knows which capabilities/resources it needs to fulfill objective. Every agent communicates with every other node in proximity to see if it can offer the capability. Examples include communicate data to the server, authorize going to lower power level, temperature reading, send an alert to local hub, send location data, triangulate location, any boxes in same group that already completed group objectives.

Nodes can be associated with items. Examples of an item includes, but are not limited to for example, a package, a box, pallet, a container, a truck or other conveyance, infrastructure such as a door, a conveyor belt, a light switch, a road, or any other thing that can be tracked, monitored, sensed, etc. or that can transmit data concerning its state or environment. In some examples, a server or a master node may associate the unique node identifiers with the items.

Communication paths between tape and/or non-tape nodes may be represented by a graph of edges between the corresponding assets (e.g., a storage unit, truck, or hub). In some embodiments, each node in the graph has a unique identifier. A set of connected edges between nodes is represented by a sequence of the node identifiers that defines a communication path between a set of nodes.

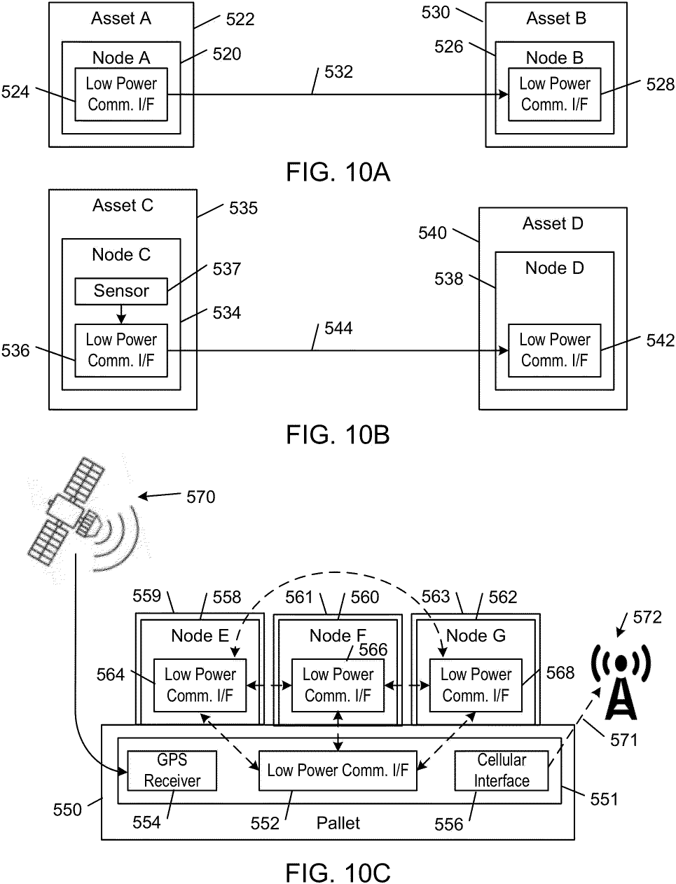

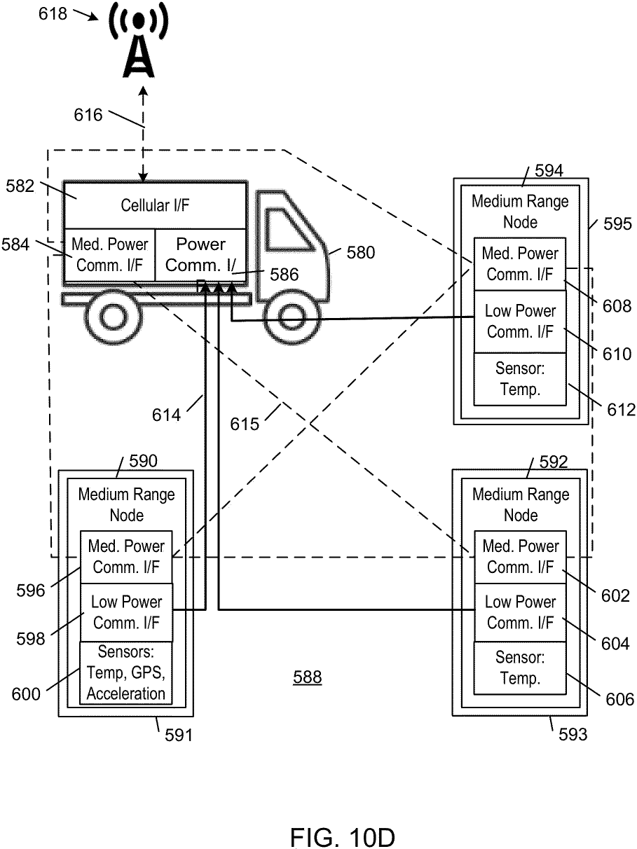

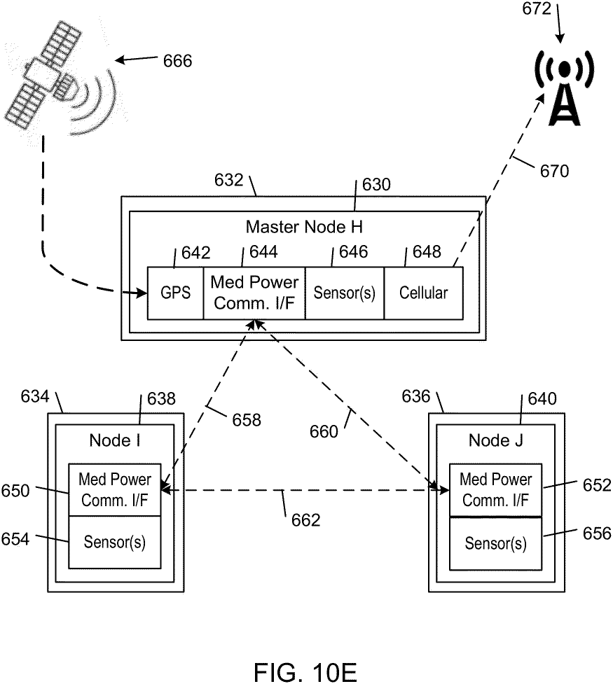

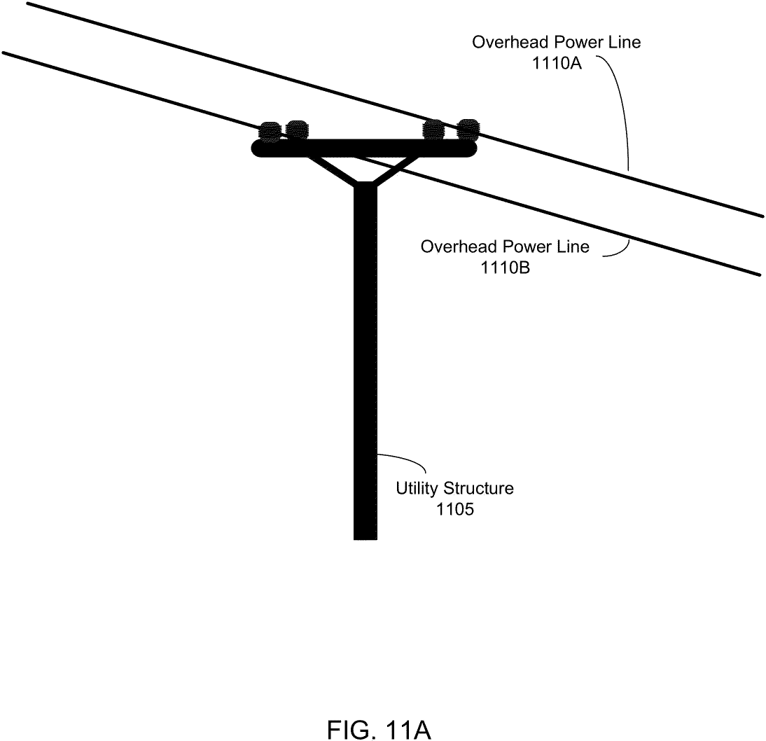

Referring to FIG. 10A, a node 520 (Node A) is associated with an asset 522 (Asset A). In some embodiments, the node 520 may be implemented as a tape node that is used to seal the asset 522 or it may be implemented as a label node that is used to label the asset 522; alternatively, the node 520 may be implemented as a non-tape node that is inserted within the asset 522 or embedded in or otherwise attached to the interior or exterior of the asset 522. In the illustrated embodiment, the node 520 includes a low power communications interface 524 (e.g., a Bluetooth Low Energy communications interface). Another node 526 (Node B), which is associated with another asset 530 (Asset B), is similarly equipped with a compatible low power communications interface 528 (e.g., a Bluetooth Low Energy communications interface).

In an example scenario, in accordance with the programmatic code stored in its memory, node 526 (Node B) requires a connection to node 520 (Node A) to perform a task that involves checking the battery life of Node A. Initially, Node B is unconnected to any other nodes. In accordance with the programmatic code stored in its memory, Node B periodically broadcasts advertising packets into the surrounding area. When the other node 520 (Node A) is within range of Node B and is operating in a listening mode, Node A will extract the address of Node B and potentially other information (e.g., security information) from an advertising packet. If, according to its programmatic code, Node A determines that it is authorized to connect to Node B, Node A will attempt to pair with Node B. In this process, Node A and Node B determine each other’s identities, capabilities, and services. For example, after successfully establishing a communication path 532 with Node A (e.g., a Bluetooth Low Energy formatted communication path), Node B determines Node A’s identity information (e.g., master node), Node A’s capabilities include reporting its current battery life, and Node A’s services include transmitting its current battery life to other nodes. In response to a request from Node B, Node A transmits an indication of its current battery life to Node B.

Referring to FIG. 10B, a node 534 (Node C) is associated with an asset 535 (Asset C). In the illustrated embodiment, the Node C includes a low power communications interface 536 (e.g., a Bluetooth Low Energy communications interface), and a sensor 537 (e.g., a temperature sensor). Another node 538 (Node D), which is associated with another asset 540 (Asset D), is similarly equipped with a compatible low power communications interface 542 (e.g., a Bluetooth Low Energy communications interface).

In an example scenario, in accordance with the programmatic code stored in its memory, Node D requires a connection to Node C to perform a task that involves checking the temperature in the vicinity of Node C. Initially, Node D is unconnected to any other nodes. In accordance with the programmatic code stored in its memory, Node D periodically broadcasts advertising packets in the surrounding area. When Node C is within range of Node D and is operating in a listening mode, Node C will extract the address of Node D and potentially other information (e.g., security information) from the advertising packet. If, according to its programmatic code, Node C determines that it is authorized to connect to Node D, Node C will attempt to pair with Node D. In this process, Node C and Node D determine each other’s identities, capabilities, and services. For example, after successfully establishing a communication path 544 with Node C (e.g., a Bluetooth Low Energy formatted communication path), Node D determines Node C’s identity information (e.g., a peripheral node), Node C’s capabilities include retrieving temperature data, and Node C’s services include transmitting temperature data to other nodes. In response to a request from Node D, Node C transmits its measured and/or locally processed temperature data to Node D.

Referring to FIG. 10C, a pallet 550 is associated with a master node 551 that includes a low power communications interface 552, a GPS receiver 554, and a cellular communications interface 556. In some embodiments, the master node 551 may be implemented as a tape node or a label node that is adhered to the pallet 550. In other embodiments, the master node 551 may be implemented as a non-tape node that is inserted within the body of the pallet 550 or embedded in or otherwise attached to the interior or exterior of the pallet 550.

The pallet 550 provides a structure for grouping and containing assets 559, 561, 563 each of which is associated with a respective peripheral node 558, 560, 562 (Node E, Node F, and Node G). Each of the peripheral nodes 558, 560, 562 includes a respective low power communications interface 564, 566, 568 (e.g., Bluetooth Low Energy communications interface). In the illustrated embodiment, each of the nodes E, F, G and the master node 551 are connected to each of the other nodes over a respective low power communications path (shown by dashed lines).

In some embodiments, the assets 559, 561, 563 are grouped together because they are related. For example, the assets 559, 561, 563 may share the same shipping itinerary or a portion thereof. In an example scenario, the master pallet node 550 scans for advertising packets that are broadcasted from the peripheral nodes 558, 560, 562. In some examples, the peripheral nodes broadcast advertising packets during respective scheduled broadcast intervals. The master node 551 can determine the presence of the assets 559, 561, 563 in the vicinity of the pallet 550 based on receipt of one or more advertising packets from each of the nodes E, F, and G. In some embodiments, in response to receipt of advertising packets broadcasted by the peripheral nodes 558, 560, 562, the master node 551 transmits respective requests to the server to associate the master node 551 and the respective peripheral nodes 558, 560, 562. In some examples, the master tape node requests authorization from the server to associate the master tape node and the peripheral tape nodes. If the corresponding assets 559, 561, 563 are intended to be grouped together (e.g., they share the same itinerary or certain segments of the same itinerary), the server authorizes the master node 551 to associate the peripheral nodes 558, 560, 562 with one another as a grouped set of assets. In some embodiments, the server registers the master node and peripheral tape node identifiers with a group identifier. The server also may associate each node ID with a respective physical label ID that is affixed to the respective asset.

In some embodiments, after an initial set of assets is assigned to a multi-asset group, the master node 551 may identify another asset arrives in the vicinity of the multi-asset group. The master node may request authorization from the server to associate the other asset with the existing multi-asset group. If the server determines that the other asset is intended to ship with the multi-asset group, the server instructs the master node to merge one or more other assets with currently grouped set of assets. After all assets are grouped together, the server authorizes the multi-asset group to ship. In some embodiments, this process may involve releasing the multi-asset group from a containment area (e.g., customs holding area) in a shipment facility.

In some embodiments, the peripheral nodes 558, 560, 562 include environmental sensors for obtaining information regarding environmental conditions in the vicinity of the associated assets 559, 561, 563. Examples of such environmental sensors include temperature sensors, humidity sensors, acceleration sensors, vibration sensors, shock sensors, pressure sensors, altitude sensors, light sensors, and orientation sensors.

In the illustrated embodiment, the master node 551 can determine its own location based on geolocation data transmitted by a satellite-based radio navigation system 570 (e.g., GPS, GLONASS, and NAVSTAR) and received by the GPS receiver 554 component of the master node 551. In an alternative embodiment, the location of the master pallet node 551 can be determined using cellular based navigation techniques that use mobile communication technologies (e.g., GSM, GPRS, CDMA, etc.) to implement one or more cell-based localization techniques. After the master node 551 has ascertained its location, the distance of each of the assets 559, 561, 563 from the master node 551 can be estimated based on the average signal strength of the advertising packets that the master node 551 receives from the respective peripheral node. The master node 551 can then transmit its own location and the locations of the asset nodes E, F, and G to a server over a cellular interface connection with a cell tower 572. Other methods of determining the distance of each of the assets 559, 561, 563 from the master node 551, such as Received Signal-Strength Index (RSSI) based indoor localization techniques, also may be used.

In some embodiments, after determining its own location and the locations of the peripheral nodes, the master node 551 reports the location data and the collected and optionally processed (e.g., either by the peripheral nodes peripheral nodes 558, 560, 562 or the master node 551) sensor data to a server over a cellular communication path 571 on a cellular network 572.

In some examples, nodes are able to autonomously detect logistics execution errors if assets that suppose to travel together no longer travel together, and raise an alert. For example, a node (e.g., the master node 551 or one of the peripheral nodes 558, 560, 562) alerts the server when the node determines that a particular asset 559 is being or has already been improperly separated from the group of assets. The node may determine that there has been an improper separation of the particular asset 559 in a variety of ways. For example, the associated node 558 that is bound to the particular asset 559 may include an accelerometer that generates a signal in response to movement of the asset from the pallet. In accordance with its intelligent agent program code, the associated node 558 determines that the master node 551 has not disassociated the particular asset 559 from the group and therefore broadcasts advertising packets to the master node, which causes the master node 551 to monitor the average signal strength of the advertising packets and, if the master node 551 determines that the signal strength is decreasing over time, the master node 551 will issue an alert either locally (e.g., through a speaker component of the master node 551) or to the server.

Referring to FIG. 10D, a truck 580 is configured as a mobile node or mobile hub that includes a cellular communications interface 582, a medium power communications interface 584, and a low power communications interface 586. The communications interfaces 580-586 may be implemented on one or more tape and non-tape nodes. In an illustrative scenario, the truck 580 visits a storage facility, such as a warehouse 588, to wirelessly obtain temperature data generated by temperature sensors in the medium range nodes 590, 592, 594. The warehouse 588 contains nodes 590, 592, and 594 that are associated with respective assets 591, 593, 595. In the illustrated embodiment, each node 590-594 is a medium range node that includes a respective medium power communications interface 596, 602, 608, a respective low power communications interface 598, 604, 610 and one or more respective sensors 600, 606, 612. In the illustrated embodiment, each of the asset nodes 590, 592, 594 and the truck 580 is connected to each of the other ones of the asset nodes through a respective medium power communications path (shown by dashed lines). In some embodiments, the medium power communications paths are LoRa formatted communication paths.

In some embodiments, the communications interfaces 584 and 586 (e.g., a LoRa communications interface and a Bluetooth Low Energy communications interface) on the node on the truck 580 is programmed to broadcast advertisement packets to establish connections with other network nodes within range of the truck node. A warehouse 588 includes medium range nodes 590, 592, 594 that are associated with respective containers 591, 593, 595 (e.g., assets, boxes, pallets, and the like). When the truck node’s low power interface 586 is within range of any of the medium range nodes 590, 592, 594 and one or more of the medium range nodes is operating in a listening mode, the medium range node will extract the address of truck node and potentially other information (e.g., security information) from the advertising packet. If, according to its programmatic code, the truck node determines that it is authorized to connect to one of the medium range nodes 590, 592, 594, the truck node will attempt to pair with the medium range node. In this process, the truck node and the medium range node determine each other’s identities, capabilities, and services. For example, after successfully establishing a communication path with the truck node (e.g., a Bluetooth Low Energy formatted communication path 614 or a LoRa formatted communication path 617), the truck node determines the identity information for the medium range node 590 (e.g., a peripheral node), the medium range node’s capabilities include retrieving temperature data, and the medium range node’s services include transmitting temperature data to other nodes. Depending of the size of the warehouse 588, the truck 580 initially may communicate with the nodes 590, 592, 594 using a low power communications interface (e.g., Bluetooth Low Energy interface). If any of the anticipated nodes fails to respond to repeated broadcasts of advertising packets by the truck 580, the truck 580 will try to communicate with the non-responsive nodes using a medium power communications interface (e.g., LoRa interface). In response to a request from the truck node 584, the medium range node 590 transmits an indication of its measured temperature data to the truck node. The truck node repeats the process for each of the other medium range nodes 592, 594 that generate temperature measurement data in the warehouse 588. The truck node reports the collected (and optionally processed, either by the medium range nodes 590, 592, 594 or the truck node) temperature data to a server over a cellular communication path 616 with a cellular network 618.

Referring to FIG. 10E, a master node 630 is associated with an item 632 (e.g., an asset) and grouped together with other items 634, 636 (e.g., assets) that are associated with respective peripheral nodes 638, 640. The master node 630 includes a GPS receiver 642, a medium power communications interface 644, one or more sensors 646, and a cellular communications interface 648. Each of the peripheral nodes 638, 640 includes a respective medium power communications interface 650, 652 and one or more respective sensors 654, 656. In the illustrated embodiment, the peripheral and master nodes are connected to one another other over respective pairwise communications paths (shown by dashed lines). In some embodiments, the nodes 630 638, 640 communicate through respective LoRa communications interfaces over LoRa formatted communications paths 658, 660, 662.

In the illustrated embodiment, the master and peripheral nodes 638, 638, 640 include environmental sensors for obtaining information regarding environmental conditions in the vicinity of the associated assets 632, 634, 636. Examples of such environmental sensors include temperature sensors, humidity sensors, acceleration sensors, vibration sensors, shock sensors, pressure sensors, altitude sensors, light sensors, and orientation sensors.

In accordance with the programmatic code stored in its memory, the master node 630 periodically broadcasts advertising packets in the surrounding area. When the peripheral nodes 638, 640 are within range of master node 630, and are operating in a listening mode, the peripheral nodes 638, 640 will extract the address of master node 630 and potentially other information (e.g., security information) from the advertising packets. If, according to their respective programmatic code, the peripheral nodes 638, 640 determine that hey are authorized to connect to the master node 630, the peripheral nodes 638, 640 will attempt to pair with the master node 630. In this process, the peripheral nodes 638, 640 and the master node and the peripheral nodes determine each other’s identities, capabilities, and services. For example, after successfully establishing a respective communication path 658, 660 with each of the peripheral nodes 638, 640 (e.g., a LoRa formatted communication path), the master node 630 determines certain information about the peripheral nodes 638, 640, such as their identity information (e.g., peripheral nodes), their capabilities (e.g., measuring temperature data), and their services include transmitting temperature data to other nodes.

After establishing LoRa formatted communications paths 658, 660 with the peripheral nodes 638, 640, the master node 630 transmits requests for the peripheral nodes 638, 640 to transmit their measured and/or locally processed temperature data to the master node 630.

In the illustrated embodiment, the master node 630 can determine its own location based on geolocation data transmitted by a satellite-based radio navigation system 666 (e.g., GPS, GLONASS, and NAVSTAR) and received by the GPS receiver 642 component of the master node 630. In an alternative embodiment, the location of the master node 630 can be determined using cellular based navigation techniques that use mobile communication technologies (e.g., GSM, GPRS, CDMA, etc.) to implement one or more cell-based localization techniques. After the master node 630 has ascertained its location, the distance of each of the assets 634, 636 from the master node 630 can be estimated based on the average signal strength of the advertising packets that the master node 630 receives from the respective peripheral node. The master node 630 can then transmit its own location and the locations of the asset nodes E, F, and G to a server over a cellular interface connection with a cell tower 672. Other methods of determining the distance of each of the assets 634, 636 from the master node 630, such as Received Signal-Strength Index (RSSI) based indoor localization techniques, also may be used.

In some embodiments, after determining its own location and the locations of the peripheral nodes, the master node 630 reports the location data the collected and optionally processed (e.g., either by the peripheral nodes peripheral nodes 634, 636 or the master node 630) sensor data to a server over a cellular communication path 670 on a cellular network 672.

### Failure Detecting Tracking Device for Electrical Power Lines

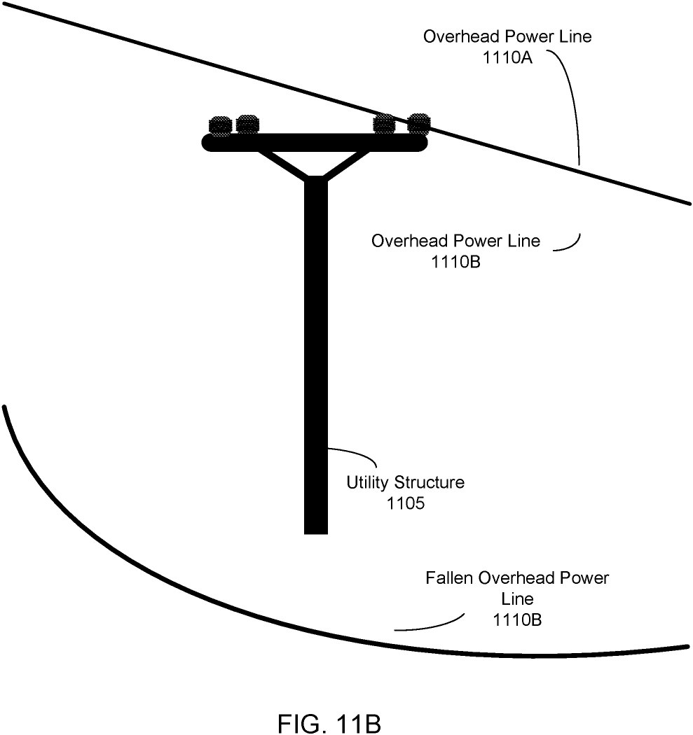

FIGS. 11A-11B show example states of overhead electrical power lines 1110A, 1110B, according to some embodiments. In FIG. 11A, the overhead electrical power lines (also referred to herein as “overhead power lines”) 1110A, 1110B are held up in the air by a utility structure 1105. The overhead power lines 1110A, 1110B may be collectively referred to as the overhead power lines 1110, overhead electrical power lines 1110, or power lines 1110, herein. The overhead power lines 1110 and the utility structure 1105 are all part of and associated with an electrical power generation, transmission, and distribution system (also referred to herein as a “power grid” or “electrical grid”) which may include, but is not limited to, power stations, electrical substations for stepping voltage up or down, electrical power transmission infrastructure, and electrical power distribution infrastructure. The utility structure may be an electrical pole, a transmission tower, or some other supporting structure for holding, guiding, and/or supporting the overhead power lines 1110A, 1110B (collectively referred to herein as). The power lines 1110 may be insulated electrical power lines or uninsulated electrical power lines. The power lines may be low voltage (less than 1000 volts), medium voltage (between 1000 volts and 69 kV), high voltage (above 69 kV), extra high voltage (above 345 kV), or ultra high voltage (above 800 kV). The power lines 1110 may be used for distribution, subtransmission, or transmission of electrical power. Although not shown here, the power lines 1110 may also be connected to ground infrastructure equipment such as transformers, electrical substations, or other electrical equipment located on the ground. In some cases, the power lines 1110 may directly connect to equipment or other parts of buildings. The power lines may also lead into the ground and extend underground to connect to equipment.

FIG. 11B shows the overhead power line 1110B in a failure state after a failure event has occurred. In the example of FIG. 11B, the failure event includes the overhead power line 1110B falling off of the utility structure 1105. The failure event results in the potential loss of power transmission and environmental hazards, such as a fire resulting from the overhead power lines coming into physical contact with objects in the environment, such as a tree or a building. In other examples, a failure event may include the overhead power line being damaged or altered, the overhead power line not conducting or transmitting power over a distance, damage or alteration to the utility structure, the utility structure falling over or leaning away from a standard position/orientation,

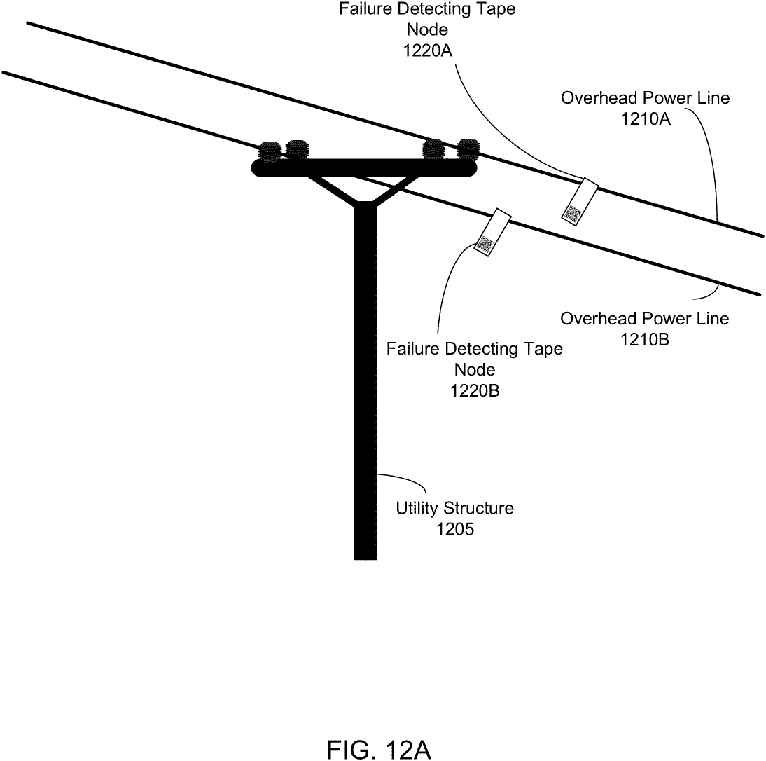

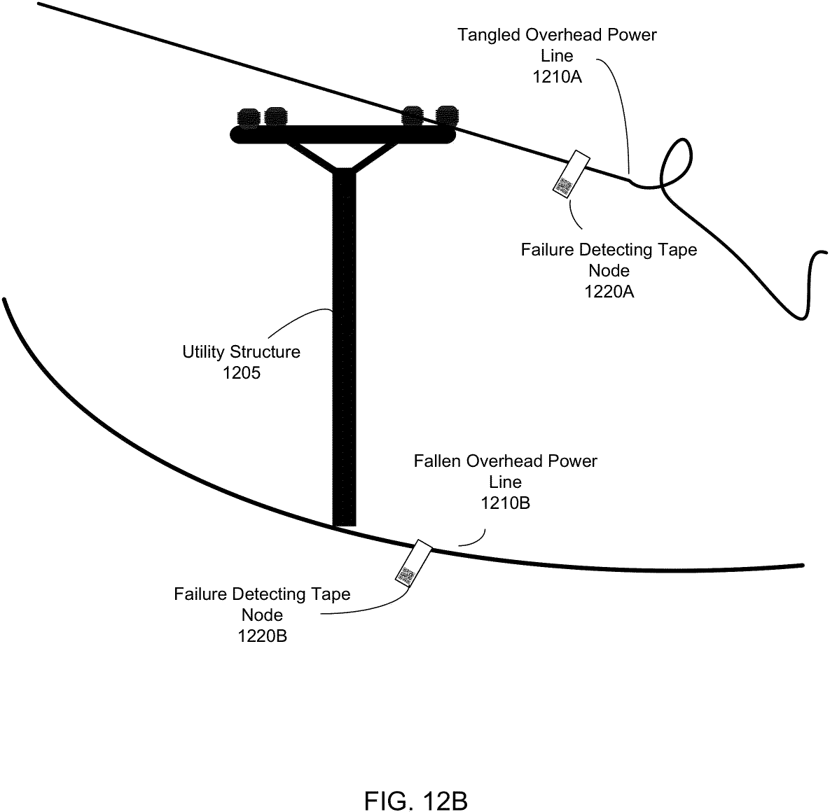

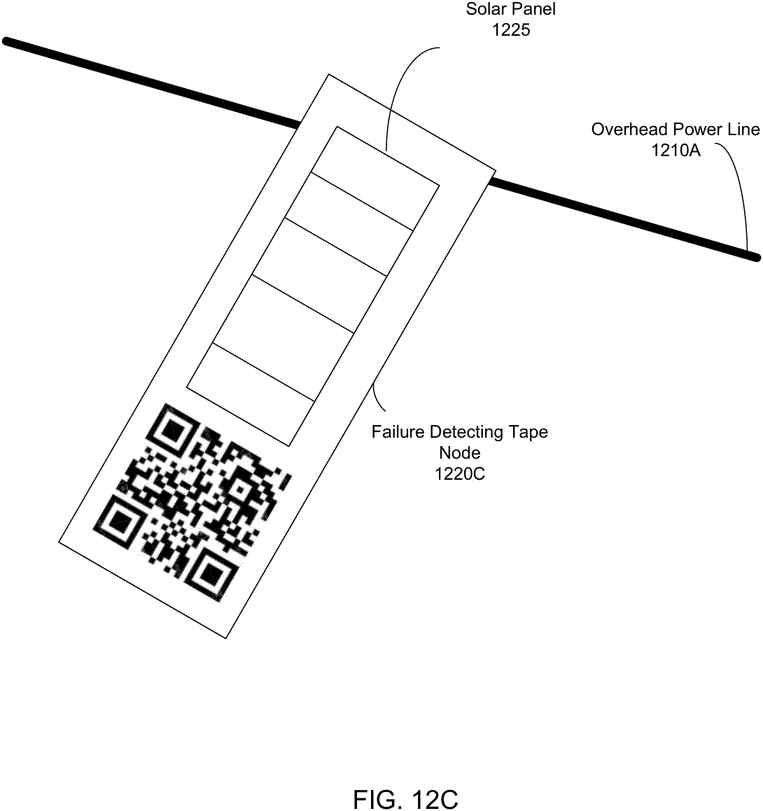

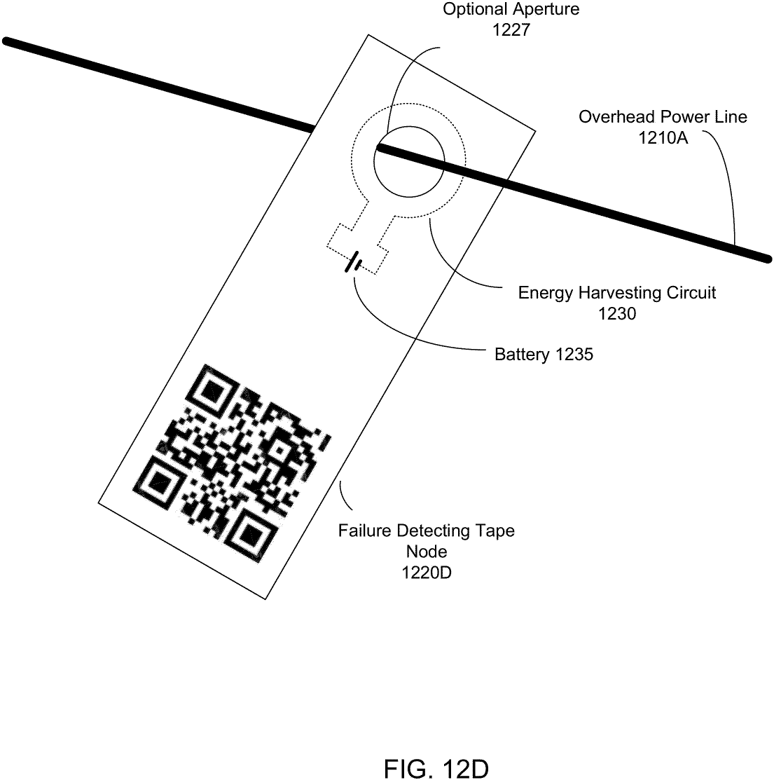

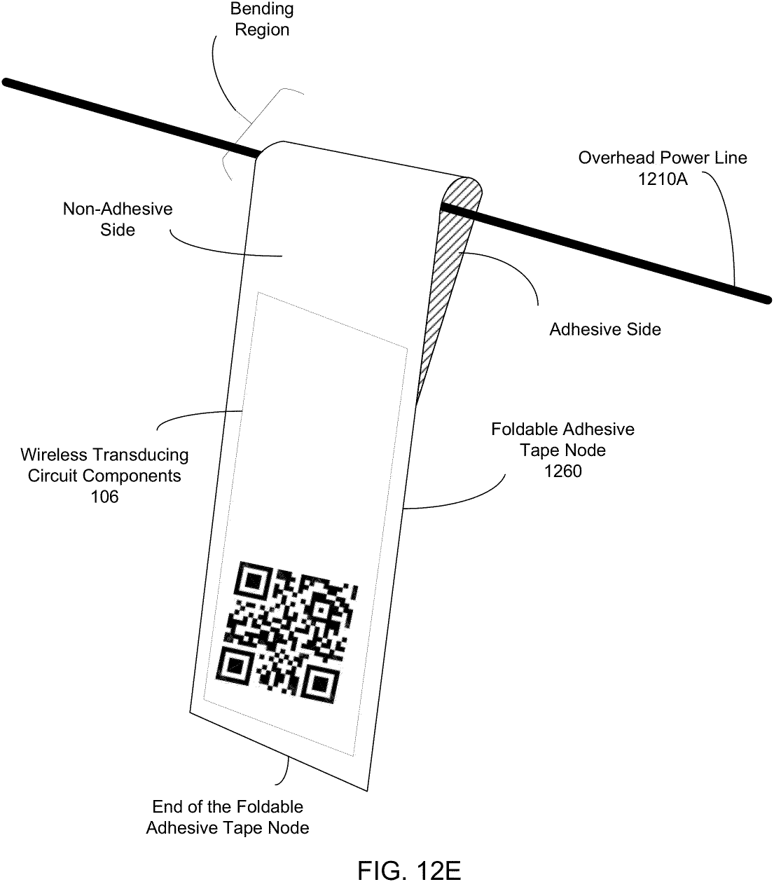

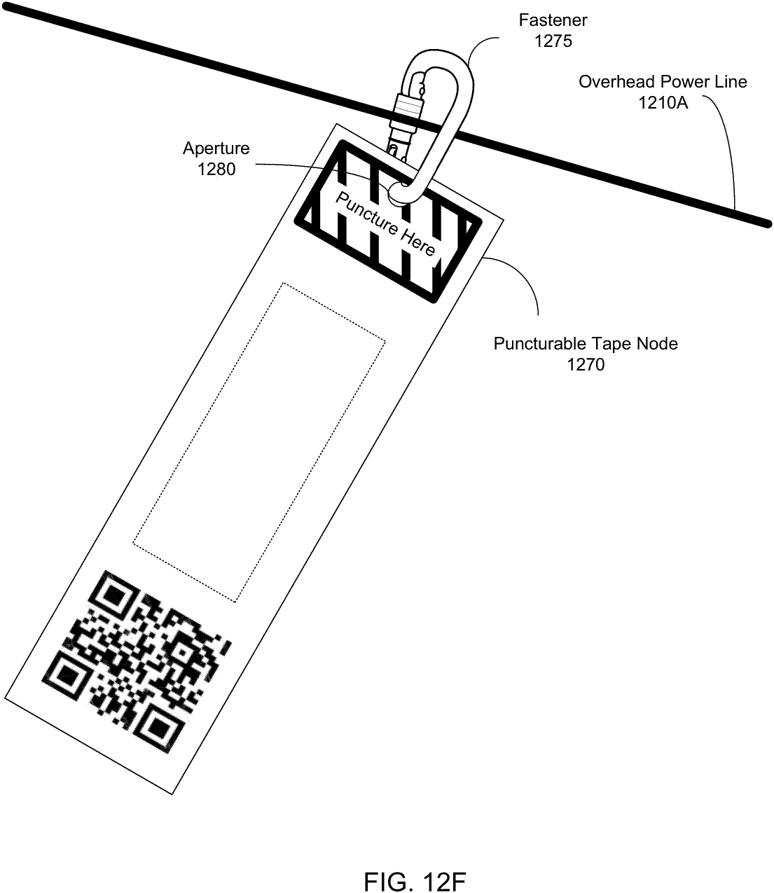

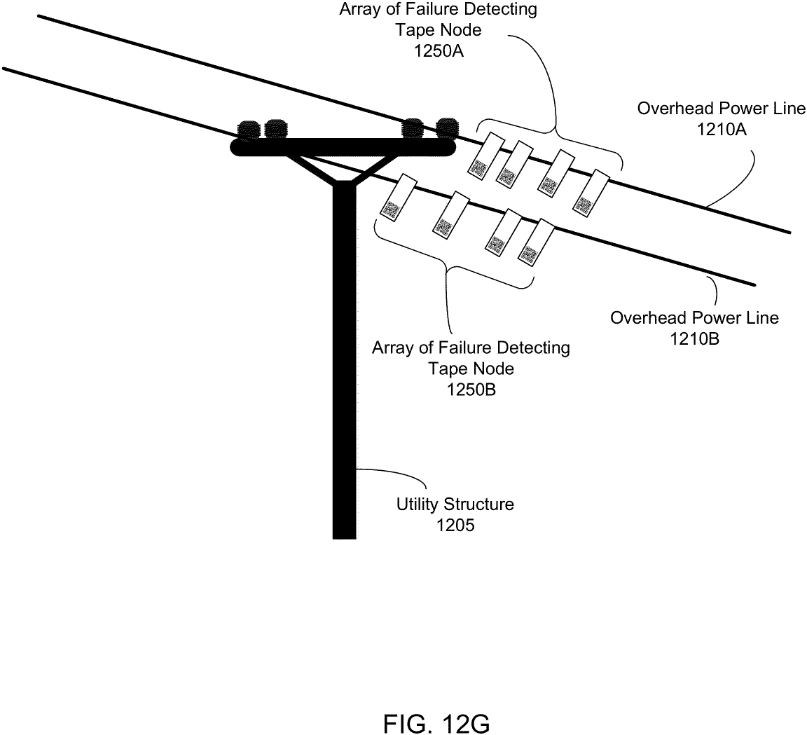

FIGS. 12A-12B show examples of detecting failure states of overhead electrical power lines 1210A, 1210B using failure detecting tape nodes 1220A, 1220B, according to some embodiments. A failure detecting tape node may include one or more sensors for detecting failure states of the respective electrical power line. The one or more sensors may include a vibration sensor, an accelerometer, an altimeter, an electrical induction sensor, an orientation sensor, a motion sensor, an electrical current sensor, an electromagnetic field sensor, a hall sensor, a voltage sensor, a temperature sensor, a heat sensor, a smoke detector sensor, a chemical sensor, a light sensor, an infrared sensor, or some other type of sensor. In some embodiments, a failure detecting tape node includes an absolute orientation or motion sensor, such as a 9-axis orientation or motion sensor that includes a combination of gyroscope sensors, accelerometers, and geomagnetic sensors for determining the orientation of a tracked object.

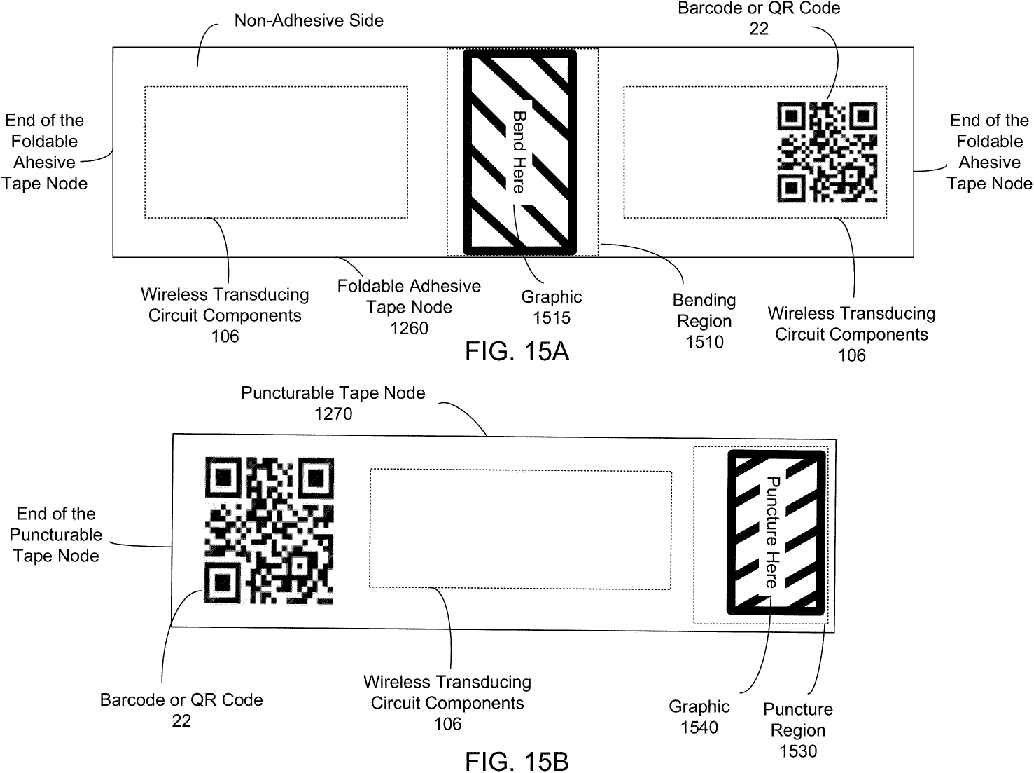

A failure detecting tape node, as discussed herein, is an embodiment of the adhesive tape platform shown in FIGS. 1A-6C and includes the wireless transducing circuit 70. A failure detecting tape node may be a flexible device with a flexible substrate 110 configured to bend at some or all portions of the failure detecting tape node, according to some embodiments, or may be a rigid device with a rigid housing and structure, according to other embodiments. Since many of the infrastructure components of an electrical grid are outdoors, the failure detecting tape node includes weatherproofing protection. This may include weatherproof materials and sealants for preventing ingress of moisture or other contaminants. For example, a substrate and cover layer of a failure detecting tape node may include weatherproof materials that act as a barrier to water and other contaminants. Additionally hydrophobic coatings, water repellant coatings, and other coatings may be applied to the failure detecting tape. Adhesives, adhesive layers (such as adhesive tapes), and epoxies may be used to seal portions of the failure detecting tape, and the adhesives, adhesive layers, and epoxies may have weatherproofing qualities such as using hydrophobic materials. Materials and construction of the failure detecting tape node may comply with weatherproofing standards such as IPX4, IPX5, IPX6, IPX6K water resistance ratings and other such standards. Various embodiments of the failure detecting tape node are shown in greater detail in FIGS. 12C-12F and FIGS. 15A-15B,

FIG. 12A shows overhead power lines 1210A, 1210B in an example normal operating condition. The power lines 1210A and 1210B include respective failure detecting tracking devices 1220A, 1220B attached to the power lines. FIG. 12B shows a first overhead power line 1210A in a first failure state, in which the first overhead power line 1210A has become tangled. FIG. 12A also shows a second overhead power line in a second failure state, where the second overhead power line 1210B has fallen off of a utility structure 1205, in this case a utility pole or a transmission tower. Each of the power lines 1210A, 1210B have a respective failure detecting tracking device 1220A, 1220B attached to the power line. In some embodiments, as shown in the FIGS. 12A-12E, the failure detecting tracking devices 1220A, 1220B are embodiments of the adhesive tape platform shown in FIG. 1-6C. The failure detecting tracking devices may also be referred to as “failure detecting tape nodes,” herein.

Each of the failure detecting tape nodes includes one or more sensors for collecting sensor data on the ambient conditions and events of the power liens 1210A, 1210B. The failure detecting tape nodes 1220A, 1220B are configured to determine if the respective power line is in a failure state, based on sensor data collected by the failure detecting tape nodes. In some embodiments, the failure detecting tape nodes wirelessly communicate with each other to determine the failure states and to validate the determinations. When a failure state is detected, the failure detecting tape nodes wirelessly communicate alerts to other nodes of the tracking system 400, and the tracking system 400 performs follow-up actions to resolve the failure states, emergencies, and other issues in the power lines 1220A, 1220B.

In some embodiments, the tracking system 400 is integrated with a controlling system for an electrical grid. For example, the tracking system 400 may provide data to a utility service provider’s control system for the electrical grid through apps, APIs, and direct communication with the tracking system 400. In response to receiving an alert, the follow-up action performed may include actions performed by the controlling system of the electrical grid. The follow-up action may be performed automatically by the controlling system software, according to some embodiments, or it may be performed manually by a utilities operator user who has access to the controlling system and data from the tracking system 400. For example, the follow-up action may include cutting off transmission of power to a section of an electrical grid. In another example, the follow-up action may include disabling or enabling functions at an electrical substation or transformer.

FIGS. 12C-12F show various examples of failure detecting tape components, according to some embodiments. FIGS. 12C-12D show examples of failure detecting tape nodes 1220C, 1220D that include energy harvesting components, according to some embodiments. In FIG. 12C, the failure detecting tape node 1220C includes a solar panel 1225 which charges a battery of the tape node 1220C when light is incident at the solar panel 1225. Since many of the infrastructure components of an electrical grid are placed outdoors, the failure detecting tape node including the solar panel 1225 may benefit from frequent or occasional exposure to sunlight.

In FIG. 12D, the failure detecting tape node includes an energy harvesting circuit 1230 which charges the battery 1235 of the tape node 1220D. The energy harvesting circuit 1230 may include an inductive loop which inductively harvests electrical energy from the electrical current flowing through the electrical power line 1210A. In some optional embodiments, the failure detecting tape node 1220D includes an aperture 1227 for the electrical power line 1210A to pass through, however the failure detecting tape node 1220D including the energy harvesting circuit is not limited to embodiments with an aperture 1227 for passing the electrical power line 1210A through and may still harvest energy from the electromagnetic fields surrounding the electrical power line 1210A without the aperture 1227. In embodiments including the aperture 1227, at least a portion of the inductive loop of the energy harvesting circuit 1230 surrounds the electrical power line 1210A and is able to harvest energy from electromagnetic fields surrounding the overhead power line 1210A due to the current transmitted through the electrical power line 1210A. In other embodiments, a portion of the failure detecting tape node 1220D including the inductive loop is wrapped around the electrical power line 1210A.

The inductive loop of the energy harvesting circuit 1230 may also be part of an induction sensing circuit used to measure changes in the electromagnetic field around the overhead power line 1210 for detecting failure events. For example, if current stops flowing through the overhead power line at a portion near or at the location of the failure detecting tape node 1220D, the failure detecting tape node 1220D will detect a corresponding change in the electromagnetic fields due to inductance using the inductive loop and induction sensing circuit. The failure detecting tape node 1220D may then determine that a change in the current flow of the power line 1210A has occurred and report the event to the tracking system 400 as a potential failure event. Similarly, if the electrical power line 1210A falls from a utility structure, the motion of the electrical power line may cause changes in the electromagnetic fields near the failure detecting tape node 1220D, which is detected by the induction sensing circuit. The failure detecting tape node 1220D may determine a potential failure event corresponding to the power line 1210A falling has occurred based on the measured changes in the electromagnetic fields and report it to the tracking system 400.

Changes in the current flowing through the line may be used to detect a fault current or risk of a future fault current. A fault current wis a current that flows through a circuit or an electrical grid during an electrical fault or failure. Changes in the current can be detected by an inductive current sensor, a current transducer, a hall sensor, or an electromagnetic field sensor that is integrated with the failure detecting tape node and can be used to detect the occurrence or the future risk of a fault current that may result in or be resultant from failure of the electrical grid.

FIGS. 12E-12F show different ways of attaching the failure detecting tape node to an overhead power line, according to some embodiments. Although not shown in FIGS. 12E-12F, the failure detecting tape nodes 1260, 1270 in FIGS. 12E-12F may include the energy harvesting components shown in FIGS. 12C-12D and other electrical components.

FIG. 12E shows a foldable adhesive tape node 1260 which is an embodiment of a failure detecting tape node which attaches to the overhead power line 1210A by being folded around the overhead power line 1210A and adhered to itself and the overhead power line 1210A. The foldable adhesive tape node 1260 is shown from another perspective in a flat, unbent state in FIG. 15A. The foldable adhesive tape node 1260 includes an adhesive side that includes an adhesive layer on the substrate and a non-adhesive side which may not include an adhesive layer on the cover layer. The foldable adhesive tape node 1260 is configured to be bent in a bending region around the overhead power line 1210A. The bending region does not contain any electronic components or circuitry that cannot withstand a radius of bending corresponding to being bent around the overhead power line 1210A. In some instances, the radius of bending in the bending region corresponds to the radius of the overhead power line 1210A. The critical electronic components and components that are not flexible are positioned outside of the bending area in the foldable adhesive tape node 1260. Conductive traces, flexible circuit boards, and other flexible electronics may be positioned to overlap with the bending region, according to some embodiments.

The foldable adhesive tape node 1260 is folded around the overhead power line 1210A, such that a portion of the foldable adhesive tape node 1260 on the adhesive side is adhered to another portion of the foldable adhesive tape node 1260 on the adhesive side. Portions of the foldable adhesive tape node 1260 on the adhesive side may also be adhered to the overhead power line 1210A itself. Optionally, a weight may be included in, on, or separately attached to the foldable adhesive tape node 1260 at one or more of the ends of the foldable adhesive tape node to aid the foldable adhesive tape node 1260 in maintaining a vertical orientation when hanging on the overhead power line 1210A, under normal operating conditions for the overhead power line 1210A. This may be used to differentiate measured changes in orientation of the foldable adhesive tape node 1260 due to environmental factors such as slight winds that are not related to failure events from measured changes in orientation that correspond to failure events.

FIG. 12F shows a puncturable tape node 1270 that is attached to the overhead power line 1210A using a fastener. In the example of FIG. 12F, the fastener 1275 passes through an aperture that is made by puncturing the puncturable tape node 1270, but in other embodiments, a different fastener may attach a failure detecting tape node to the overhead power line 1210A, without needing to pass through an aperture in the failure detecting tape node. For example, a fastener may attach to a failure detecting tape node using a clip, vise, or clamp that grips a portion of the failure detecting tape node. The fastener 1275 in FIG. 12F is a device that attaches to the puncturable tape node 1270 by passing through the aperture 1280 and looping or hooking around the overhead power line 1210A. The fastener 1275 appears as a carabiner in FIG. 12F, but in other embodiments, the fastener 1275 may be a hook, a loop, a string, a cord, a wire, a nail, a piece of hardware, or some other type of fastener. The puncturable tape node 1270 is shown from another perspective in FIG. 12B. Similar to the bending region of the foldable adhesive tape node 1260, the puncturable tape node 1270 includes a puncture region that does not include electrical components that would be damage from being punctured. Further discussion of a puncture region in an adhesive tape node platform may be found in U.S. Patent Application No. 17/558,556, filed on Dec. 21, 2021, which is incorporated herein in its entirety.

In some embodiments, the aperture 1280 is made by a user puncturing the puncturable tape node 1270 in a puncture region of the tape node 1270 at a time of installation or before installing the tape node 1270 on the overhead power line 1210A. In other embodiments, the aperture 1280 may be pre-made in the tape node 1270 before the user receives the tape node 1270 or at a time of manufacturing the tape node 1270. For example, the aperture 1280 may be made by a hole punch, a drill, a cutting tool, or some other tool. In some embodiments, the aperture 1280 may be made by pushing or moving a sharp portion of a fastener through the puncture region of the tape node 1270. In other embodiments, a perforation in the tape node 1270 may be made in the a shape of the aperture 1280 that aids the user in creating the aperture with a tool or by hand at a time of installation, by cutting or tearing along the perforation.

FIG. 12G shows an example of using an array of failure detecting tape nodes 1250A, 1250B (collectively referred to as the failure detecting tape node arrays 1250 or the arrays of failure detecting tape nodes 1250) on a respective electrical power line 1210A, 1210B to detect a failure state of the electrical power line, according to some embodiments. An array of failure detecting tape nodes 1250A may use each tape node in the array 1250A to redundantly detect failure states of the respective electrical power line 1210A. The tape nodes in the arrays may communicate with each other to quickly validate determined failure states or operating conditions with low latency, by performing validation locally at the tape nodes (e.g., using the computational power of the tape nodes) without needing to communicate with a server or another remote device.

For example, if one of the failure detecting tape nodes in the array 1250A detects a potential failure event based on its sensor readings corresponding to the overhead power line 1210A falling off of the utility structure 1205, the one failure detecting tape node may communicate with the other tape nodes in the array 1250A to determine if the other tape nodes also have sensor readings that correspond to the same or a similar event. If more than a threshold number of the tape nodes in the array 1250A report back to the one failure detecting tape node that a same or similar event has been detected, the one failure detecting tape node may then validate its own detection of the failure event without having to communicate with a server or other remote entity in the tracking system 400. This allow for low latency validation of failure event detection. The one failure detecting tape node may then respond by reporting the detected failure event to another wireless node of the tracking system 400. The other wireless node may be a tape node attached to the utility structure 1205 or a tape node or gateway located elsewhere. In some embodiments, a failure detecting tape node may include cellular or satellite communication systems and may directly transmit a notification of the detected event to the tracking system 400 using a cellular network connection.

For critical use cases, such as monitoring high voltage electrical power lines, redundant monitoring may be beneficial for accurate detection of failure events. Redundant monitoring may also decrease the risk of failure to detect events. For example, if only a single failure detecting tape node is used, a malfunctioning of the failure detecting tape node may result in the tracking system 400 may result in a failure event not being detected or not being detected quickly by the tracking system 400. Failure to detect a catastrophic event in time may result in undesirable or dangerous conditions, property damage, power outage, and other risks. The arrays of failure detecting tape nodes 1250 allow for higher assurance that a failure event will not be missed by tracking system 400.

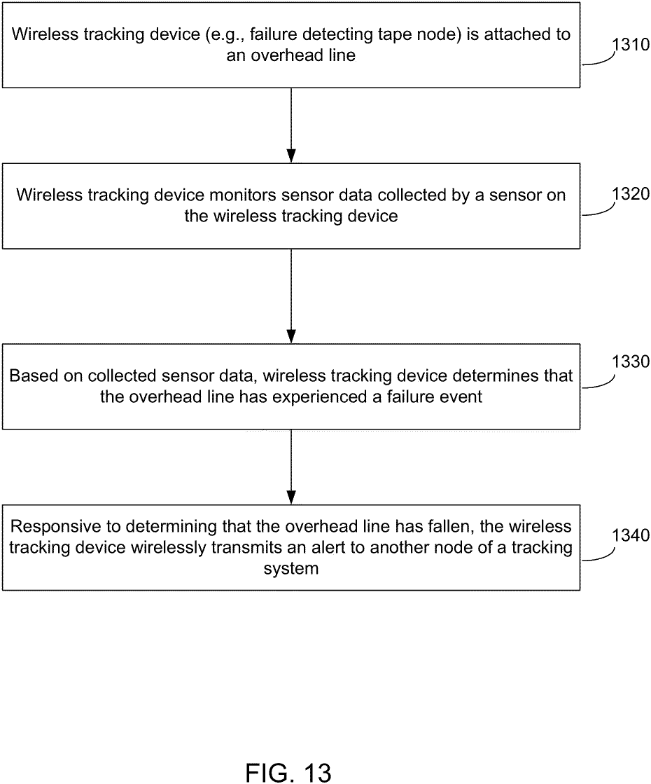

FIG. 13 is a flow chart for an example method 1301 of detecting that an overhead line has experienced a failure event, according to some embodiments. The overhead line is any line, wire, cable, structure or portion of a structure that is suspended in the air. The method 1301 includes attaching 1310 a wireless tracking device (e.g., failure detecting tape node) an overhead power line. The wireless tracking device monitors 1320 sensor data collected by one or more sensor on the wireless tracking device. In some examples, the sensor is a vibration sensor or an accelerometer which detects the motion of the overhead power line. Based on collected sensor data, the wireless tracking device determines 1330 that the overhead line has experienced a failure event. For example, a wireless tracking device including an accelerometer may measure acceleration data when the overhead power line falls from a utility structure (e.g., an electrical pole or a transmission tower) towards the ground. Comparing the measured acceleration data to known acceleration data signatures for a falling overhead power line, the wireless tracking device may detect a failure event corresponding to the overhead power line falling off the utility structure. Responsive to determining that the overhead line has experienced a failure event, the wireless tracking device wirelessly transmits 1440 an alert to another node of a tracking system. The alert may be transmitted to a nearby wireless node, such as a gateway node for bridging communications from the failure detecting tape nodes and a server of the wireless communication system. In other examples, the alert may be transmitted to a tape node that is on a nearby utility structure. The alert may be wirelessly transmitted to nearby wireless nodes using short range wireless communication systems and protocols such as Bluetooth or WiFi, to wireless nodes at further distances using medium range wireless communication systems and protocols such as LoRa or LoRaWAN, or over long ranges using long range wireless communication systems such as cellular communications (e.g., 3G, 4G, LTE, 5G cellular and data communications) or satellite communications.

In the case that a failure event is detected, a server of the tracking system may receive the alert and perform a follow-up action. The follow-up action may include notifying a user of the tracking system 400 or an operator of a utility service provider, making changes to the operation of a utility service, such as cutting off power to a region of the electrical grid surrounding the wireless tracking device, notifying emergency services, dispatching service people for a repair or intervention, or by broadcasting alarms and messages to people near the wireless tracking device. For example, in the event of a fallen overhead power line, the tracking system 400 and the operator of the utility service provider may transmit audio (over a phone call) and text messages to the phones of users known to be located in an area near where the overhead power line has fallen, to warn them to evacuate in case of a potential catastrophic fire.

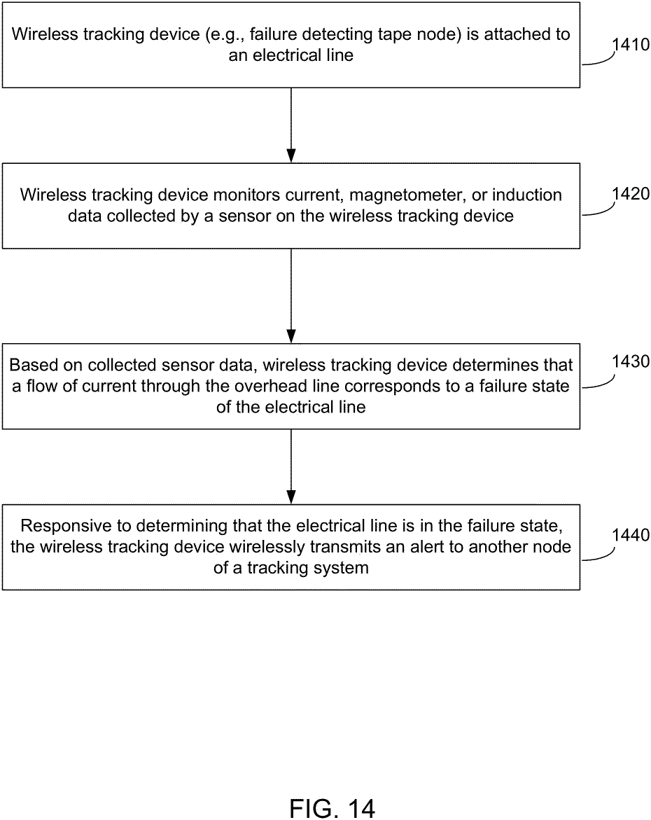

FIG. 14 is a flow chart for an example method 1401 of detecting a failure state of an electrical line, according to some embodiments. The electrical line may be an overhead power line, an underground power line, or another type of electrical line. In other embodiments, the electrical line is not part of an electrical grid but is another type of line that carries electrical current. The method 1401 includes attaching 1410 a wireless tracking device (e.g., failure detecting tape node) to an overhead line. The wireless tracking device monitors 1420 electrical current data corresponding to electrical current flowing through the electrical line, magnetometer data, or induction data collected by a sensor on the wireless tracking device. For example, the wireless tracking device may include an induction sensor that measures changes in the electromagnetic fields outside of the electrical line. Based on collected sensor data, the wireless tracking device determines 1430 that an uncharacteristic flow of current is occurring in the electrical line which corresponds to a failure state of the overhead line. The flow of the current may be below a low threshold value or above a high threshold value, in some embodiments. In other embodiments, the electrical current may be an alternating current and the frequency of the alternating current may be below a low threshold value or above a high threshold value. In some embodiments, the uncharacteristic flow of current may be detected based on detecting jitter in the current, noise, or some other property.

Responsive to determining that the electrical line is in the failure state, the wireless tracking device wirelessly transmits 1440 an alert to another node of a tracking system. The same discussion above with respect to step 1330 in FIG. 13 applies to the wireless transmission 1430 of the alert.

FIGS. 15A-15B show examples of failure detecting tape nodes, according to various embodiments. FIG. 15A shows an example of the foldable adhesive tape node 1260 from a perspective showing the non-adhesive side. The foldable adhesive tape node includes wireless transducing components 106 in regions that do not overlap the bending region 1510. Only components that are flexible, flexible conductive traces, and flexible circuit boards are located in areas that overlap the bending region 1510. A graphic 1515 displays areas where users may fold or bend the tape node 1260 without damaging the internal electronics and text to guide the users where to fold the device, according to some embodiments. Additional graphics may warn users not to bend the tape node 1260 in areas outside of the bending region 1510.

Optionally, the foldable adhesive tape node 1260 may include a weight that is located at one of the ends of the foldable adhesive tape node 1260, away from the center of the tape node 1260. The tape node 1260 may include weights at both ends. The weight may be positioned inside the tape node or on the outside of the tape node attached to the exterior of the substrate or cover layer. In other embodiments, a weight is not included in or on the tape node 1260, but the components of the tape node 1260 are arranged such that the weight of the tape node 1260 is distributed not at the center, but at the ends.

FIG. 15B shows an example of the puncturable tape node 1270. The puncturable tape node 1270 includes a puncture region 1530 and a graphic 1540 which indicates the position of the puncture region and includes text instructions for users. The puncturable tape node 1270 may also include a weight on or in the tape node 1270 at the end of the puncturable tape node away from the end where the tape node attaches to the overhead power line.

### System for Detecting Failure Events and Response in an Electrical Grid

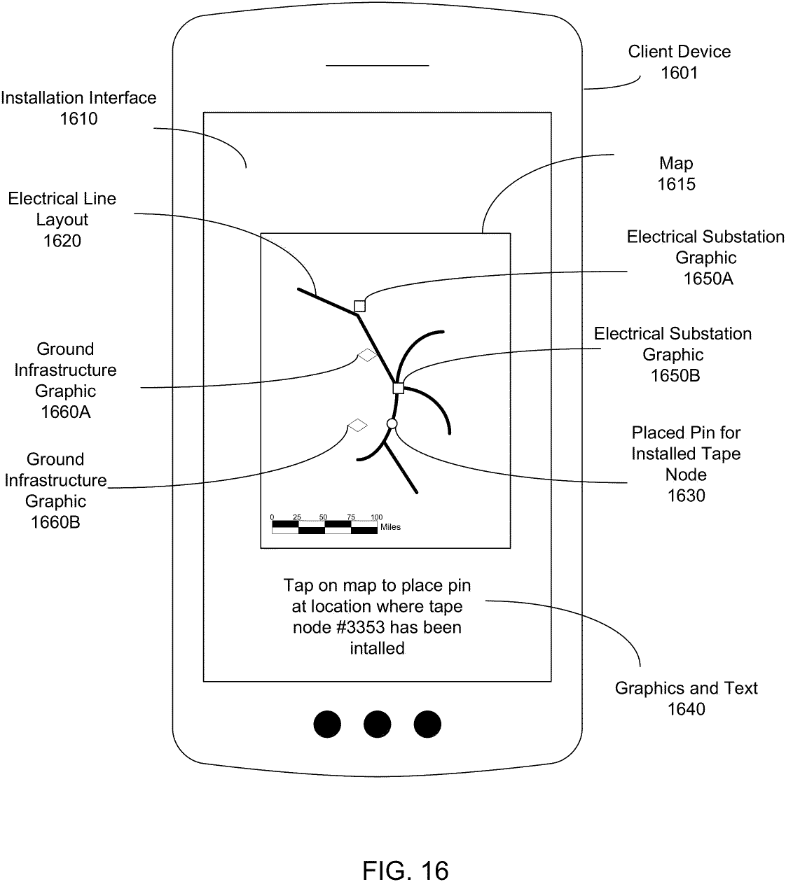

FIG. 16 is an example diagram of a client device displaying an installation interface 1610 for an app used to track tape nodes installed on electrical lines 1620, according to some embodiments. A user of the app may install a tape node at a location on an electrical line and then mark the location of the tape node with a pin 1630 on a map 1615 shown in the interface 1610. The app may then update a database on a server of the tracking system 400, according to the inputs from the user on the interface 1610 indicating the location and other information on the installed tape node. Locations for infrastructure components of the electrical grid may also be represented in the installation interface 1610 overlaid on the map 1615. Examples include graphical elements which represent the location of substations 1650A, 1650B and graphical elements that represent the location of ground infrastructure equipment 1660A, 1660B. The installation interface 1610 may also display graphical elements representing the locations of other failure detecting tape nodes and other wireless nodes of the tracking system 400 that are associated with the electrical grid which have previously been installed and have had their locations registered to the tracking system.

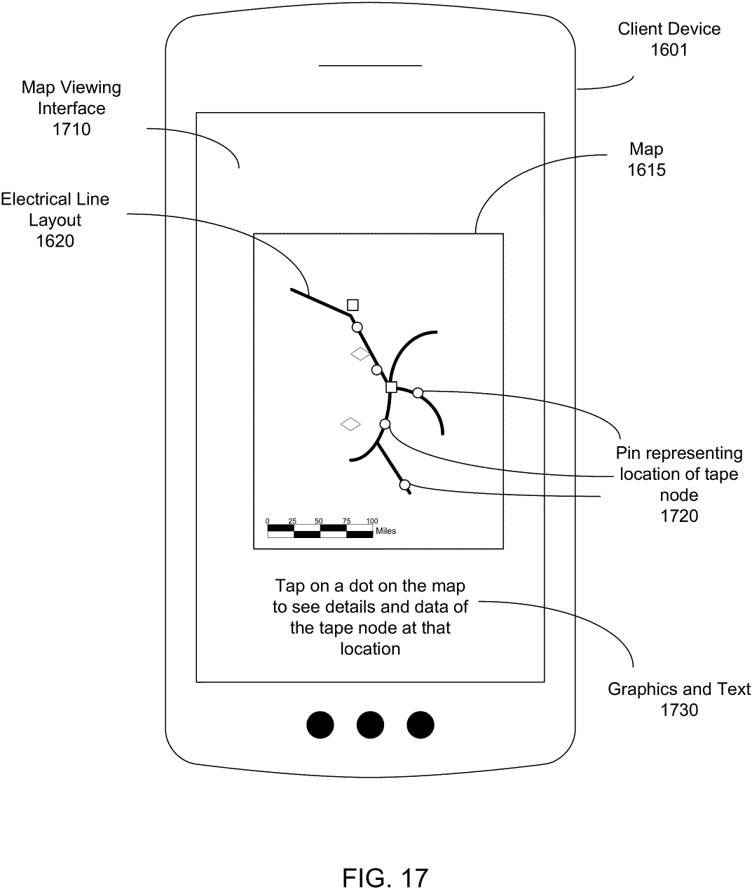

FIG. 17 is an example diagram of a client device 1601 displaying a map viewing interface 1710 for an app used to track tape nodes and other wireless nodes of the tracking system 400 installed on or near electrical lines 1620 and other electrical grid infrastructure components, according to some embodiments. The map viewing interface 1610 may display the same map 1615 and the same layout of the electrical lines 1620 in an area, as is displayed in the installation interface 1610, according to some embodiments. The map viewing interface 1710, displays the locations of previously installed tape nodes on electrical lines 1620 in an area corresponding to the map 1615. The locations are indicated by pins 1720 overlaid on the map 1615. The app may receive the location data and other data from a database of the tracking system 400. In the example of FIG. 17, the pins are represented by circles on the interface 1710, however in other embodiments, other graphical representations may be used. In further embodiments, the map viewing interface 1710 also displays information on each of the tape nodes (e.g., operational status, sensor data, etc.) on the interface overlaid on the map 1615. The information may be displayed as text or represented graphically. For example, the operational status of a tape node may be represented by a color of a pin corresponding to the location for that tape node.

When a user provides an input corresponding to a selection of one of the pins 1720, the map viewing interface displays additional details on the failure detecting tape node represented by the selected pin. The additional detail may include an identifier of the tape node, data on the electrical grid infrastructure object being monitored by the tape node, a current status of the tape node, a current status of the electrical grid infrastructure object being monitored, sensor data, a log of events detected by the tape nod, other data, or some combination thereof. The additional detail may be displayed in another window or in a popup that is overlaid in the map viewing interface 1710.

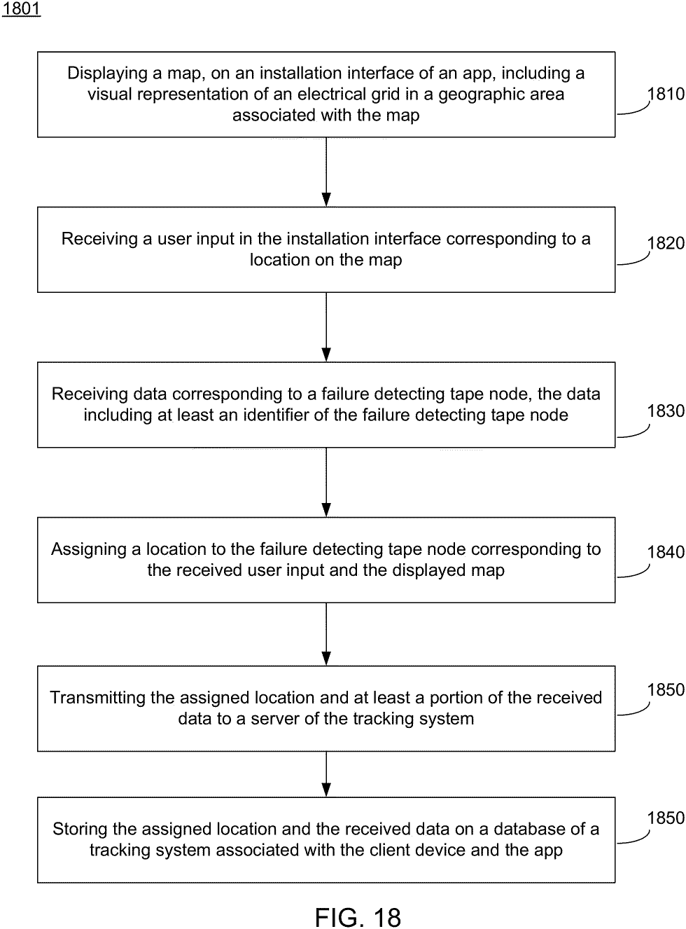

FIG. 18 is a flow chart for an example method 1801 of assigning a location to a failure detecting tape node using an installation interface on a client device app, according to some embodiments. The method 1801 includes displaying 1810 a map, on an installation interface of an app or web app displayed on a client device, including a visual representation of an electrical grid in a geographic area associated with the map. The installation interface may also display graphical node elements representing the locations of failure detecting tape nodes and other wireless nodes that have previously been installed and are registered (with a location already assigned to them) in the tracking system 400 overlaid on the map. Infrastructure components of the electrical grid may additionally be represented in the installation interface on the map. The app receives 1820 a user input in the installation interface corresponding to a location on the map. The user input is made by the user on the client device to indicate the location on the map where a failure detecting tape node has been installed. The user input may be a touch input on a touchscreen, a selection using a user input device such as a mouse or keyboard, or some other input. For example, using a touchscreen on a smartphone or tablet, the user may tap a location on the map that corresponds to the geographic location where the failure detecting tape node is installed. The app also receives 1830 data corresponding to a failure detecting tape node, the data including at least an identifier of the failure detecting tape node. The data may be received 1830 by a user inputting the data manually in the installation interface or by wireless communication between the client device and the failure detecting tape node. The app assigns 1840 a location to the failure detecting tape node corresponding to the received user input and the displayed portion of the map in the installation interface. In other embodiments, the location is assigned based on location data of the client device and not based on the user input. For example, if the client device is a smartphone, the location may be assigned based on location data on the smartphone’s location based on cellular triangulation or trilateration or based on GPS location data. The client device then transmits 1850 the assigned location and at least a portion of the data received from the failure detecting tape node to a server of the tracking system which stores 1850 the assigned location and the location’s association with the failure detecting tape node in a database, along with other data received from the client device.

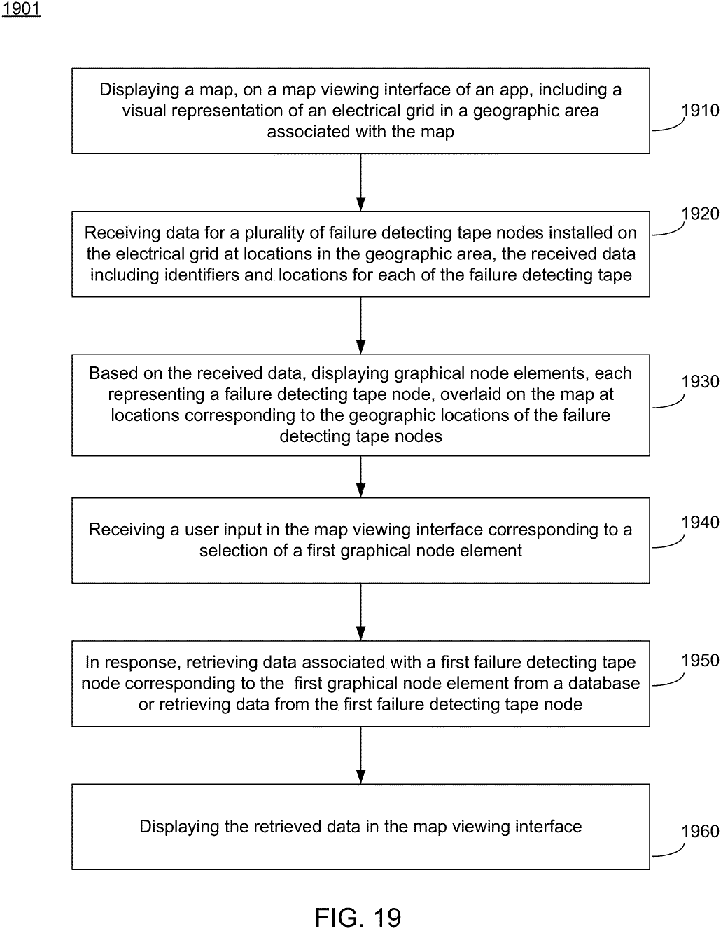

FIG. 19 is a flow chart for an example method 1901 of displaying the locations of and data from failure detecting tape nodes on a map viewing interface on an app or web app, according to some embodiments. The method 1901 includes displaying 1910 a map, on a map viewing interface of an app or web app displayed on a client device, including a visual representation of an electrical grid in a geographic area associated with the map. Receiving 1920 data at the client device from a server of the tracking system 400 for a plurality of failure detecting tape nodes installed on the electrical grid at locations in the geographic area, the received data including identifiers and location data for each of the failure detecting tape. The location data may be based on location data assigned to tape nodes during an installation and initialization process such as the one described above with respect to FIG. 18 using an installation interface in the same app on the client device. Based on the received data, the map viewing interface displays 1930 graphical node elements, each representing a failure detecting tape node or, overlaid on the map at locations corresponding to the geographic locations of the failure detecting tape nodes. The graphical node elements are graphical symbols or text representing the locations of the failure detecting tape nodes. Additionally, other wireless nodes of the tracking system and infrastructure components of the electrical grid may be represented in the map viewing interface. In the map viewing interface, a user input is received 1940 corresponding to a selection of a first graphical node element displayed in the map viewing interface. The user input may be a touch input on a touchscreen, a selection using a user input device such as a mouse or keyboard, or some other input. For example, the user may tap a touch screen displaying the map viewing interface at a location of the first graphical node element. In response, the app retrieves 1950 data associated with a first failure detecting tape node corresponding to the first graphical node element from a database. Alternatively, the app may cause the client device to directly retrieve 1950 data from the first failure detecting tape node 1950 over a wireless communication connection. The data may include an identifier for the failure detecting tape node, an identifier for an infrastructure component of the electrical grid associated with the failure detecting tape node, an operational status of the failure detecting tape node, a determination of the operational status of the electrical grid at the location of the failure detecting tape node, sensor data captured by the failure detecting tape node, a log of events detected by the failure detecting tape node, other data, or some combination thereof. At least a portion of the retrieved data or data based on the retrieved data is then displayed 1960 in the map viewing interface.

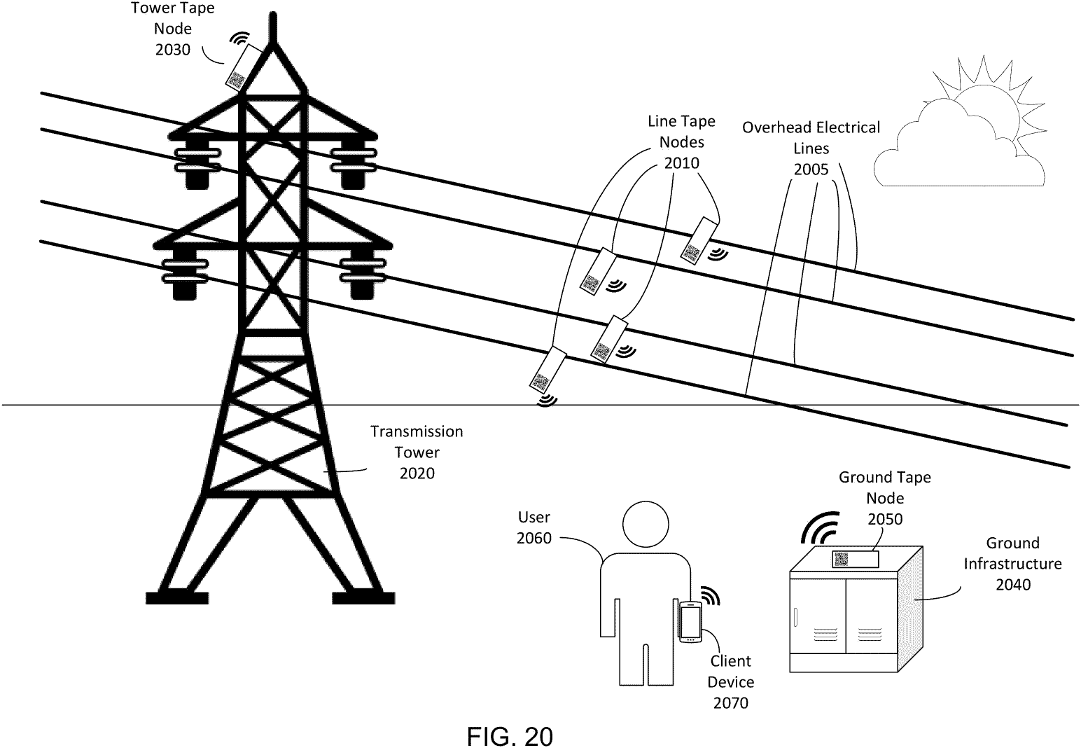

FIG. 20 shows an example portion of a system 2101 for detecting failure events for infrastructure components of an electrical grid, according to some embodiments. The portion of the system includes failure detecting tape nodes 2010 each installed on an overhead electrical line 2005. The overhead electrical line 2005 may be supported by a utility structure such as a nearby transmission tower 2020. The system also includes a failure detecting tape node 2030, referred to herein as a tower tape node 2030 on the transmission tower 2020. Near the overhead electrical lines 2005, a ground infrastructure equipment 2040 may be installed on the ground that is associated with the electrical grid that includes the overhead electrical lines 2005 and the transmission tower 2020. The ground infrastructure 2040 may include any equipment associated with the electrical grid. Examples include, but are not limited to, pad mounted transformers, step-down transformers, step-up transformers, and other electrical infrastructure equipment. A tape node 2050 or a gateway device may be installed at or inside the ground infrastructure.

The failure detecting tape nodes 2030 on the transmission tower 2020 may monitor conditions of the electrical grid that differ from those monitored by the failure detecting tape nodes 2010 installed on the overhead electrical lines 2005. Similarly, the tape node 2050 on the ground infrastructure may monitor conditions of the electrical grid that differ from those monitored by the failure detecting tape nodes 2010 installed on the overhead electrical lines 2005 and the tower tape nodes 2030 installed on the transmission tower 2020. For example, the tower tape nodes 2030 may measure a tilt of the transmission tower 2020 to detect if a transmission tower is leaning or about to fall over. In another example, the ground tape node 2050 may monitor temperature for detecting failure of the ground infrastructure equipment 2040 caused by heat or temperature.

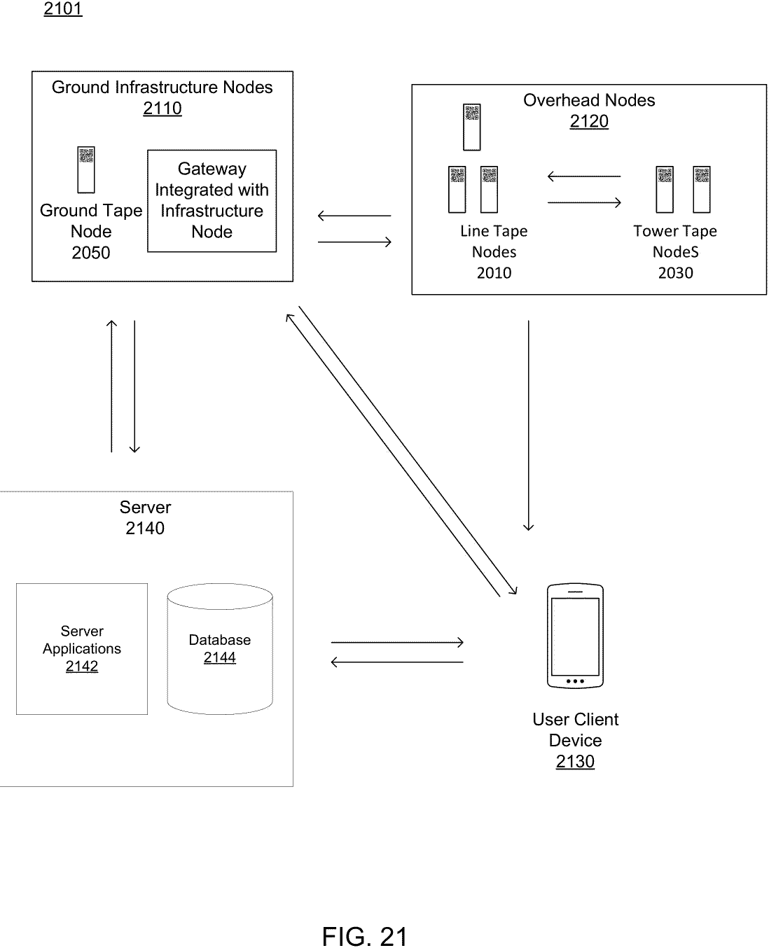

FIG. 21 is an interaction diagram for the example portion of a system 2101 for detecting failure events for infrastructure components of an electrical grid shown in FIG. 20, according to some embodiments. The ground infrastructure nodes 2110 (including any tape nodes and gateway devices installed near, on, or in ground infrastructure equipment) communicate with nearby overhead nodes 2120 including failure detecting tape nodes installed on overhead electrical lines, transmission towers, and other utility structures. The ground infrastructure nodes 2110 may act as a master which collects sensor data and logs events detected by the failure detecting tape nodes that are nearby, according to some embodiments. The ground infrastructure nodes 2110 may upload data to client devices 2130 of users that are nearby or to a server 2140 of the failure detecting system. The failure detecting system may maintain a database of sensor data and events detected. The server may also send notifications and instructions to the user’s client device 2130. For example, the server may prompt a user via an app on the client device to perform intervention or repairs at a location in the electrical grid where a failure event has been detected by the failure detecting system.

In some embodiments, the ground infrastructure nodes are capable of controlling functions and change configurations of the ground infrastructure equipment that they are associated with. For example, the ground infrastructure nodes may instruct the associated ground infrastructure equipment perform an intervention action, such as deenergizing the ground infrastructure equipment or deenergizing a portion of the electrical grid affected by a failure event. In some examples, the ground infrastructure equipment may be equipment configured to control the transmission of electricity through portions of the electrical grid, such as lengths of overhead power lines. This may be done to avoid a dangerous scenario or prevent a hazardous condition such as a fire. In embodiments, the ground infrastructure nodes can intervene with the ground infrastructure equipment without needing to communicate with the server 2140, in order to reduce latency between the detection of a failure event and the implementation of an intervention action. In an example, a failure detecting tape node 2010 detects that a overhead power line has fallen from a utility structure towards the ground and transmits an alert of the fall event to the ground infrastructure node 2110. In response, the ground infrastructure node instructs the ground infrastructure equipment to deenergize the overhead power line that has fallen.

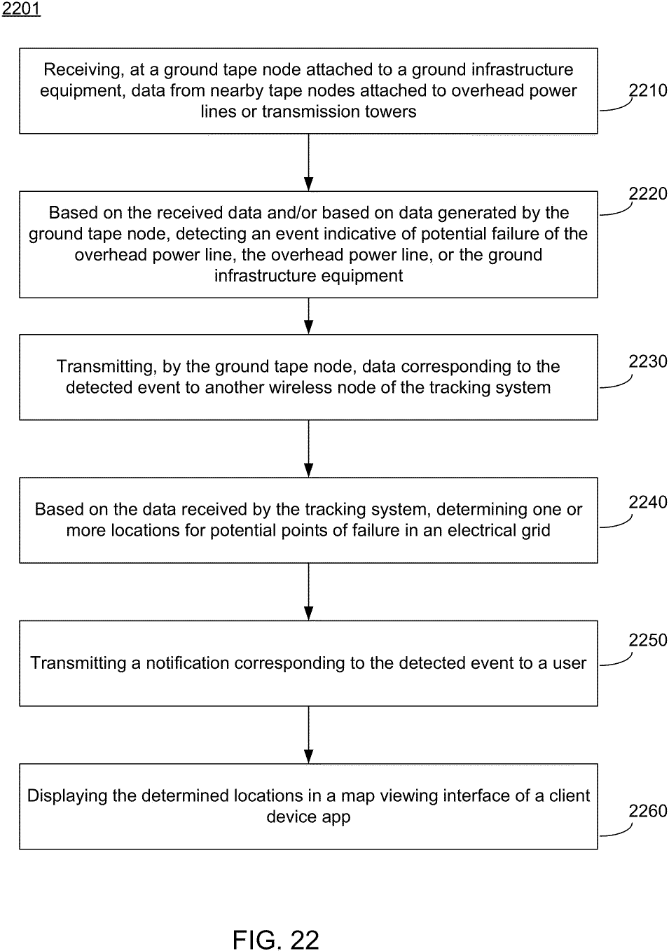

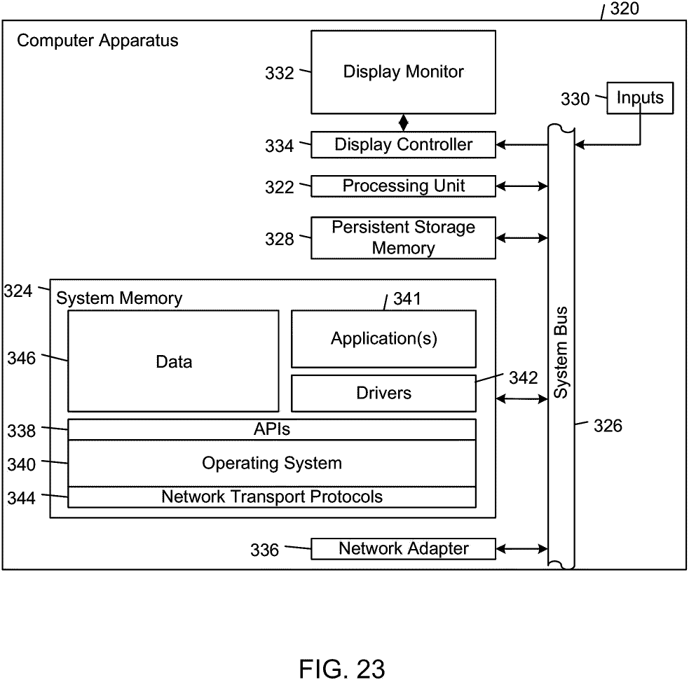

FIG. 22 is a flow chart for an example method 2201 of determining locations of potential points of failure in an electrical grid using a system for failure detection, according to some embodiments. The system for failure detection includes the tracking system 400 or components of the tracking system 400. The method includes receiving, at a ground tape node attached to a ground infrastructure equipment, data from nearby failure detecting tape nodes. The nearby failure detecting tape nodes may be attached to overhead power lines and/or one or more transmission towers. Based on the received data and/or based on data generated by the ground tape node, the ground tape node detects 2220 an event indicative of potential failure of the overhead power line, the overhead power line, or the ground infrastructure equipment. The event may include detecting that an overhead power line has fallen from a utility structure, that a ground infrastructure equipment has malfunctioned, that an overhead power line has become damaged, that electrical transmission has stopped or is under a threshold level of current or voltage, that the electrical transmission is over a threshold level of current or voltage, some other event indicative of failed electrical power transmission, or some combination thereof, according to some embodiments.

The ground tape node then transmits 2230, data corresponding to the detected event to another wireless node of the tracking system 400. The other wireless node may be another tape node, a gateway device, another communication device, a user client device, or a server of the tracking system 400. The data may be relayed through the tracking system 400 until it is received by a server of the tracking system 400, according to some embodiments. Based on the data received by the tracking system, one or more locations for potential points of failure in an electrical grid are determined 2240. For example, other ground tape nodes may report similar failure events and the tracking system may determine multiple points of failure. Further, the tracking system may determine an origin point of the failure where an event that has caused the failure occurred. The tracking system responds by transmitting 2250 a notification corresponding to the detected event to a user. The user may be an operator of the utility service associated with the electrical grid being monitored by the system for failure detection. Additionally, the determined locations are displayed 2260 in a map viewing interface of a client device app associated with the system for failure detection. For example, the locations may be shown in the map viewing interface 1710 shown in FIG. 17. Optionally, the ground tape node may transmit instructions to the ground infrastructure equipment to deenergize the ground infrastructure equipment or deenergize a portion of the electrical grid, in response to determining that a failure event has occurred.

### Computer Apparatus

FIG. 22 shows an example embodiment of computer apparatus 320 that, either alone or in combination with one or more other computing apparatus, is operable to implement one or more of the computer systems described in this specification.

The computer apparatus 320 includes a processing unit 322, a system memory 324, and a system bus 326 that couples the processing unit 322 to the various components of the computer apparatus 320. The processing unit 322 may include one or more data processors, each of which may be in the form of any one of various commercially available computer processors. The system memory 324 includes one or more computer-readable media that typically are associated with a software application addressing space that defines the addresses that are available to software applications. The system memory 324 may include a read only memory (ROM) that stores a basic input/output system (BIOS) that contains start-up routines for the computer apparatus 320, and a random access memory (RAM). The system bus 326 may be a memory bus, a peripheral bus or a local bus, and may be compatible with any of a variety of bus protocols, including PCI, VESA, Microchannel, ISA, and EISA. The computer apparatus 320 also includes a persistent storage memory 328 (e.g., a hard drive, a floppy drive, a CD ROM drive, magnetic tape drives, flash memory devices, and digital video disks) that is connected to the system bus 326 and contains one or more computer-readable media disks that provide non-volatile or persistent storage for data, data structures and computer-executable instructions.

A user may interact (e.g., input commands or data) with the computer apparatus 320 using one or more input devices 330 (e.g. one or more keyboards, computer mice, microphones, cameras, joysticks, physical motion sensors, and touch pads). Information may be presented through a graphical user interface (GUI) that is presented to the user on a display monitor 332, which is controlled by a display controller 334. The computer apparatus 320 also may include other input/output hardware (e.g., peripheral output devices, such as speakers and a printer). The computer apparatus 320 connects to other network nodes through a network adapter 336 (also referred to as a “network interface card” or NIC).

A number of program modules may be stored in the system memory 324, including application programming interfaces 338 (APIs), an operating system (OS) 340 (e.g., the Windows® operating system available from Microsoft Corporation of Redmond, Washington U.S.A.), software applications 341 including one or more software applications programming the computer apparatus 320 to perform one or more of the steps, tasks, operations, or processes of the locationing and/or tracking systems described herein, drivers 342 (e.g., a GUI driver), network transport protocols 344, and data 346 (e.g., input data, output data, program data, a registry, and configuration settings).

Examples of the subject matter described herein, including the disclosed systems, methods, processes, functional operations, and logic flows, can be implemented in data processing apparatus (e.g., computer hardware and digital electronic circuitry) operable to perform functions by operating on input and generating output. Examples of the subject matter described herein also can be tangibly embodied in software or firmware, as one or more sets of computer instructions encoded on one or more tangible non-transitory carrier media (e.g., a machine readable storage device, substrate, or sequential access memory device) for execution by data processing apparatus.

The details of specific implementations described herein may be specific to particular embodiments of particular inventions and should not be construed as limitations on the scope of any claimed invention. For example, features that are described in connection with separate embodiments may also be incorporated into a single embodiment, and features that are described in connection with a single embodiment may also be implemented in multiple separate embodiments. In addition, the disclosure of steps, tasks, operations, or processes being performed in a particular order does not necessarily require that those steps, tasks, operations, or processes be performed in the particular order; instead, in some cases, one or more of the disclosed steps, tasks, operations, and processes may be performed in a different order or in accordance with a multi-tasking schedule or in parallel.

Other embodiments are within the scope of the claims.

### Additional Embodiments

Failure detecting tape nodes are attached to electrical power line (e.g., overhead power line). Failure detecting tape nodes are configured to detect a failure state of the electrical power line. An example failure state would be a state where an overhead power line has fallen down or fallen off of an electrical pole, tower (e.g., transmission tower), utility pole, or some other structure. Failure detection for electrical or overhead lines using the failure detecting tape node is not limited to detecting failure in electrical power lines. In some embodiments, failure detection may be used to detect failure in any line or object that is suspended in the air or hung overhead.

The failure detecting tape nodes are part of a failure detection system which enables low latency, continuous detection of failure states and failure events. The failure detection system includes the tracking system 400 or components of the tracking system 400. Failure events are events that may results in a potential failure state of the line. The failure detection system may be coupled to a controlling system of the electrical grid that allows the electrical grid to disable or deenergize a transformer when a nearby or associated power line falls or experiences a failure state.

The failure detection system uses low latency communication between local wireless nodes to quickly detect failure states and perform responsive actions. Failure states may be detected by failure detecting tape nodes using vibration sensing, accelerometers for detecting motion of the power lines corresponding to the lines falling down, becoming twisted or tangled, or other mechanical failure, inductive sensing for detecting excursions of electromagnetic waves that correspond to power line failure.

If failure detecting tape node detects a failure state, the tape nodes wirelessly report to a wireless node of the tracking system. Some failure detecting tape nodes may be equipped with cellular or satellite communications systems and may report directly to a server of the tracking system.

In response to detecting failure, the failure detection system may perform response actions. When the tape node reports the failure state of an electrical power line, the power line operator (e.g., utility service operator) may de-power, de-energize, or deactivate the power line, in response. This may be to avoid an emergency situation like a fire outbreak. The failure detecting tape nodes may report the failure state of the electrical power line falling off a utility structure (e.g., utility pole, transmission tower, etc.) before the electrical power line hits the ground or hits structures below the power line (e.g., trees, buildings, etc.). In response, the electrical power line is deenergized before the electrical power line hits the ground, buildings, or other structures, avoiding risk of an emergency situation or hazard.

Before a fault current is detected or an electrical line falls to ground, a failure detecting tape node or other tracking device sends signal to an associated transformer to deenergize the line. This in essence makes the electrical line a “Smart Wire” by attaching the failure detecting tape node to the electrical line. Edge computing is performed at the failure detecting tape nodes for immediate decision and support. Additionally, the network of failure detecting tape nodes tracked by the failure detection system allow the system to pinpoint exactly where the issue causing failure is located for repair and diagnosis.

Gateways or tape nodes local to the power line perform computations to determine failure states of the electrical power line. Low latency achieved by computing and communicating locally to the electrical power line, minimizing the need for wireless communications which add latency to the overall system.

The failure detecting system may detect emergencies that are related to or affect the electrical grid. For example, failure detecting tape node may include one or more temperature sensors. The failure detecting tape node may determine risk of wild fire based on detected temperature and transmit alerts based on determined risk.

If an emergency situation is detected, the failure detecting tape node may make a call (using a cellular communication system) to an emergency service (e.g., fire department or 911). Additionally or alternatively, the failure detecting tape node may report directly to the server of the tracking system or to an operator of the tracking system.

In embodiments, a failure detecting tape node is wrapped around an electrical line/conductor. The tape node may include an inductive loop and an inductive sensor circuit coupled to the inductive loop for detecting changes in electromagnetic fields induced by changes in the current in the electrical line/conductor. In some embodiments, a failure detecting tape node is attached to the side of a transformer to measure temperature, vibration, tilt of the transformer. The senso data is reported to the tracking system and failure detection system.

Raise alerts based on excursions of the tracked sensor data from baseline readings. Failure detecting tape node may charge off induction, in some embodiments, thus never needing to replace sensors, according to some embodiments. Alternatively, failure detecting tape node may include a solar panel which charges the tape node.

### Additional Configuration Information

The foregoing description of the embodiments of the disclosure have been presented for the purpose of illustration; it is not intended to be exhaustive or to limit the disclosure to the precise forms disclosed. Persons skilled in the relevant art can appreciate that many modifications and variations are possible in light of the above disclosure.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, hardware, or any combinations thereof.

Any of the steps, operations, or processes described herein may be performed or implemented with one or more hardware or software modules, alone or in combination with other devices. In one embodiment, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations herein. This apparatus may be specially constructed for the required purposes, and/or it may comprise a general-purpose computing device selectively activated or reconfigured by a computer program stored in the computer. Such a computer program may be stored in a non-transitory, tangible computer readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may comprise information resulting from a computing process, where the information is stored on a non-transitory, tangible computer readable storage medium and may include any embodiment of a computer program product or other data combination described herein.

Finally, the language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

What is claimed is:

1. A wireless tracking device comprising:
circuit components comprising:
a first wireless communication system,
a processor,
a memory or storage, and
a first sensor operable to measure conditions of the wireless tracking device,
a battery;
a circuit connecting the circuit components and the battery, wherein
the wireless tracking device is configured to attach to an overhead electrical line and detect failure events that are experienced by the overhead electrical line based on sensor data monitored by the wireless tracking device.

2. The wireless tracking device of claim 1, wherein the first sensor is a vibration sensor or accelerometer.

3. The wireless tracking device of claim 2, wherein the wireless tracking device is configured to detect a failure event corresponding to the overhead power line falling from a structure towards the ground based on vibration data or accelerometer data measured by the first sensor.

4. The wireless tracking device of claim 3, wherein the wireless tracking device is configured to analyze the vibration data or accelerometer data to determine whether a failure event has occurred.

5. The wireless tracking device of claim 1, wherein the wireless tracking device is associated with a tracking system and is configured to report any detected failure events to another wireless communication device associated with the tracking system.

6. The wireless tracking device of claim 5, wherein the other wireless communication device is another wireless tracking device.

7. The wireless tracking device of claim 5, wherein the other wireless tracking device is also attached to an overhead electrical line.

8. The wireless tracking device of claim 5, wherein the tracking system responds to the received report by deenergizing a transformer associated with the overhead electrical line.

9. The wireless tracking device of claim 5, wherein the other wireless communication device is a wireless tracking device or gateway device associated with a transformer.

10. The wireless tracking device of claim 1, wherein the first sensor comprises one or more of an inductive current sensor, a hall effect sensor, a current transducer, and an electromagnetic field sensor.

11. The wireless tracking device of claim 10, wherein the wireless tracking device is configured to detect a fault current or detect a risk of a future fault current occurring based on an electrical current measurement of the overhead electrical line.

12. The wireless tracking device of claim 1, wherein the first sensor is an orientation sensor.

13. The wireless tracking device of claim 12, wherein the first sensor is a 9-axis absolute orientation sensor.

14. The wireless tracking device of claim 1, wherein the first sensor is one or more of: a temperature sensor, a voltage sensor, a moisture or humidity sensor, a pressure sensor, an optical sensor, an infrared sensor, a GPS sensor, a time of flight sensor, a depth sensor, an ultrasonic sensor, and a sound sensor.

15. A system comprising:
a first plurality of failure detecting wireless tracking devices each attached to a respective overhead electrical line of an electrical grid and configured to detect failure events of the respective overhead electrical lines based on sensor data collected by the first plurality of failure detecting wireless tracking devices,
a second plurality of failure detecting wireless tracking devices each attached to a respective transmission tower or electrical pole of the electrical grid and configured to detect failure events of the respective transmission tower or electrical pole based on sensor data collected by the second plurality of failure detecting wireless tracking devices;
a third plurality of failure detecting wireless tracking devices each attached to a transformer of the electrical grid configured to detect failure events of the respective transformer based on sensor data collected by the third plurality of failure detecting wireless tracking devices; and
a server which executes a server application that communicates with and collects data from the first, second, and third plurality of failure detecting wireless tracking devices, wherein the server maintains a database storing data for the system.

16. The system of claim 15, further comprising a client device associated with a user and configured to display data received from the server on the first, second, and third plurality of failure detecting tape nodes in an interface of an app associated with the system.

17. The system of claim 15, wherein the system further comprises a software controller of the electrical grid configurable to activate and deactivate functions of transformers of the electrical grid.

18. The system of claim 17, wherein, in response to one of the failure detecting tape nodes detecting a failure event, the software controller automatically deenergizes a transformer associated with a portion of the electrical grid corresponding to a location where the failure event was detected.

19. The system of claim 14, wherein each of the first plurality of failure detecting tape nodes are configured to detect failure events comprising one or more of: the respective overhead electrical line falling from a structure towards the ground, the respective overhead electrical line becoming twisted or tangled, the respective overhead electrical line becoming damaged, a fault current flowing through the respective overhead electrical line, the respective overhead electrical line being moved, the respective overhead electrical line coming into contact with an object, less than a threshold amount of current flowing through the electrical line, more than a threshold amount of current flowing through the electrical line, a voltage of the electrical.

20. The system of claim 14, wherein each of the second plurality of failure detecting tape nodes are configured to detect failure events comprising one or more of: the respective transmission tower or electrical pole tilting away from a standard position, the respective transmission tower experiencing vibration corresponding to an impact of an object against the transmission tower or electrical poleor corresponding to a falling of the transmission tower or electrical pole, the respective transmission tower being caught on fire, and the respective transmission tower losing one or more electrical lines previously being supported by the transmission tower.
